(19) United States
(12) Patent Application Publication
(10) Pub. No.: US 2025/0359277 A1
(43) Pub. Date: Nov. 20, 2025

(54) Gate Bar in Isolation Region of Gate Layout and Method of Fabrication Thereof

(71) Applicant: Taiwan Semiconductor Manufacturing Company, Ltd., Hsin-Chu (TW)

(72) Inventor: Shao-Jyun Wu, New Taipei City (TW)

(21) Appl. No.: 19/283,878

(22) Filed: Jul. 29, 2025

Related U.S. Application Data
(63) Continuation of application No. 18/596,885, filed on Mar. 6, 2024.
(60) Provisional application No. 63/591,205, filed on Oct. 18, 2023.

(51) Int. Cl. H10D 64/27; H01L 21/76; H10D 30/43; H10D 30/67; H10D 62/10; H10D 64/01; H10D 64/23; H10D 84/83

(52) U.S. Cl. CPC H10D 64/519; H01L 21/76; H10D 64/017; H10D 30/43; H10D 30/6735; H10D 30/6757; H10D 62/121; H10D 64/258; H10D 84/83

(57) ABSTRACT

Gate layouts and/or devices implementing gate support structures (e.g., gate bars) to in non-active region areas (e.g., isolation regions), along with methods of fabrication thereof, are described herein. An exemplary gate support structure is connected to at least two gates (e.g., two to six, in some embodiments) that are disposed in a non-active region area. The at least two gates extend lengthwise along a first direction, and the gate support structure extends lengthwise along a second direction that is different than the first direction. The gate support structure and the at least two gates may be disposed on a substrate isolation structure, such as a shallow trench isolation (STI) structure. A composition and/or configuration of the gate support structure may be the same as or different than a composition and/or a configuration of the at least two gates.

This application is a continuation of U.S. patent application Ser. No. 18/596,885, filed Mar. 6, 2024, which is a non-provisional application of and claims benefit of U.S. Provisional Patent Application Ser. No. 63/591,205, filed Oct. 18, 2023, the entire disclosures of which are incorporated herein by reference.

### BACKGROUND

The integrated circuit (IC) industry has experienced exponential growth. Technological advances in IC materials and design have produced generations of ICs, where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a device, in portion or entirety, having gate support structures, according to various aspects of the present disclosure.

FIGS. 2A-8A are top views of a device (e.g., a gate-all-around transistor or a fin-like field effect transistor), in portion or entirety, at various fabrication stages, such as those associated with the method in FIG. 1, according to various aspects of the present disclosure.

FIGS. 2B-8B are cross-sectional views of the device, in portion or entirety, along lines B-B of FIGS. 2A-8A, respectively, according to various aspects of the present disclosure.

FIGS. 2C-8C are cross-sectional views of the device, in portion or entirety, along lines C-C of FIGS. 2A-8A, respectively, according to various aspects of the present disclosure.

FIGS. 2D-8D are cross-sectional views of the device, in portion or entirety, along lines D-D of FIGS. 2A-8A, respectively, according to various aspects of the present disclosure.

FIGS. 3E-8E are cross-sectional views of the device, in portion or entirety, along lines E-E of FIGS. 3A-8A, respectively, according to various aspects of the present disclosure.

FIGS. 3F-8F are cross-sectional views of the device, in portion or entirety, along lines F-F of FIGS. 3A-8A, respectively, according to various aspects of the present disclosure.

FIG. 7G and FIG. 8G are cross-sectional views of the device, in portion or entirety, along lines G-G of FIG. 7A and FIG. 8A, respectively, according to various aspects of the present disclosure.

FIGS. 9-12 are different top views of the device of FIGS. 2A-8A, in portion or entirety, after undergoing processing associated with FIGS. 2A-2D and FIGS. 3A-3D, according to various aspects of the present disclosure.

FIG. 13A provides a top view and a cross-sectional view of a device, in portion or entirety, without gate support structures, according to various aspects of the present disclosure.

FIG. 13B provides a top view and a cross-sectional view of a device, in portion or entirety, with gate support structures, according to various aspects of the present disclosure.

FIGS. 14A-14C are various views of a device, in portion or entirety, having gate support structures, which may be fabricated according to the method of FIG. 1, configured and arranged according to design rules, according to various aspects of the present disclosure.

FIG. 15 is a flow chart of a method for fabricating a device, in portion or entirety, having gate support structures, according to various aspects of the present disclosure.

### DETAILED DESCRIPTION

The present disclosure is generally directed to gate layouts for devices, such as gate layouts for gate-all-around (GAA) transistors, and devices resulting therefrom.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” may encompass a dimension range from 4.5 nm to 5.5 nm where manufacturing tolerances associated with depositing the material layer are known to be +/−10% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Gate layouts and/or devices implementing gate support structures (e.g., gate bars) to reduce peeling, collapsing, bending, etc. of gates in non-active region areas (e.g., isolation regions), along with methods of fabrication thereof, are described herein. An exemplary gate support structure is connected to at least two gates (e.g., two to six, in some embodiments) that are disposed in a non-active region area. The at least two gates extend lengthwise along a first direction, and the gate support structure extends lengthwise along a second direction that is different than the first direction. The gate support structure and the at least two gates may be disposed on a substrate isolation structure, such as a shallow trench isolation (STI) structure. The gate support structure may be formed at the same time as the at least two gates. A composition and/or configuration of the gate support structure may be the same as or different than a composition and/or a configuration of the at least two gates. In some embodiments, the gate support structure and the at least two gates may be a polysilicon bar and polysilicon gates, respectively. In some embodiments, the gate support structure and the at least two gates each include a gate dielectric and a gate electrode. In some embodiments, the gate support structure and the at least two gates are formed at the same time as gates of transistors (i.e., active gates). The active gates may extend lengthwise along the first direction. In some embodiments, the gate support structure and the at least two gates are formed at a different time than the active gates. Dimensions of the gate support structure and/or spacings between the gate support structure and other structures (e.g., source/drain contacts, gate isolation structures, etc.) may be configured to minimize risk of electrical shorting and/or minimize residue defects.

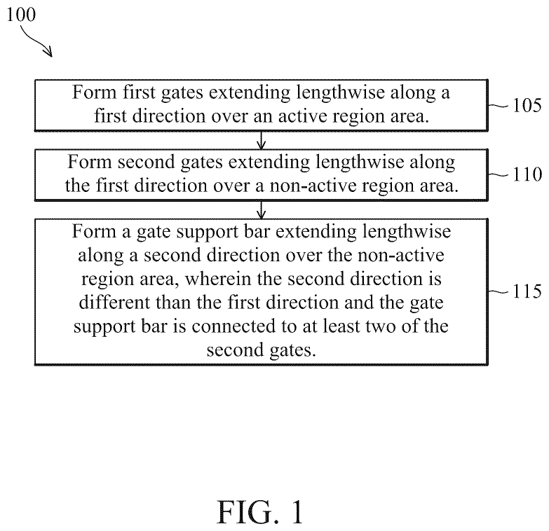

FIG. 1 is a flow chart of a method 100 for fabricating a device, in portion or entirety, having gate support structures, according to various aspects of the present disclosure. At block 105, method 100 includes forming first gates extending lengthwise along a first direction over an active region area. The active region area includes active regions, and an active region may include and/or be processed to have channel structures and source/drains, where the channel structures are disposed between respective source/drains. The first gates may be disposed on the channel structures. In some embodiments, the active region area is a device region. At block 110, method 100 includes forming second gates extending lengthwise along the first direction over a non-active region area. The non-active region area is free of active regions, and the non-active region area may include and/or be processed to have an isolation structure, such as a substrate isolation structure. The second gates may be disposed on the isolation structure. In some embodiments, the isolation structure is also in the active region area, the isolation structure may bound and/or surround the active region, and the first gates may be disposed on the isolation structure. In some embodiments, the non-active region area is an isolation region. At block 115, method 100 includes forming a gate support bar extending lengthwise along the second direction over the non-active region area. The second direction is different than the first direction, and the gate support bar is connected to at least two second gates. The gate support bar may be disposed on the isolation structure. In some embodiments, the active region extends lengthwise along the second direction. In some embodiments, the gate support bar is a third gate. In some embodiments, the first gates, the second gates, and the third gates are formed at the same time. Additional processing is contemplated by the present disclosure. Additional steps may be provided before, during, and after method 100, and some of the steps described may be moved, replaced, or eliminated for additional embodiments of method 100. The discussion that follows illustrates various embodiments of devices that may be fabricated according to method 100.

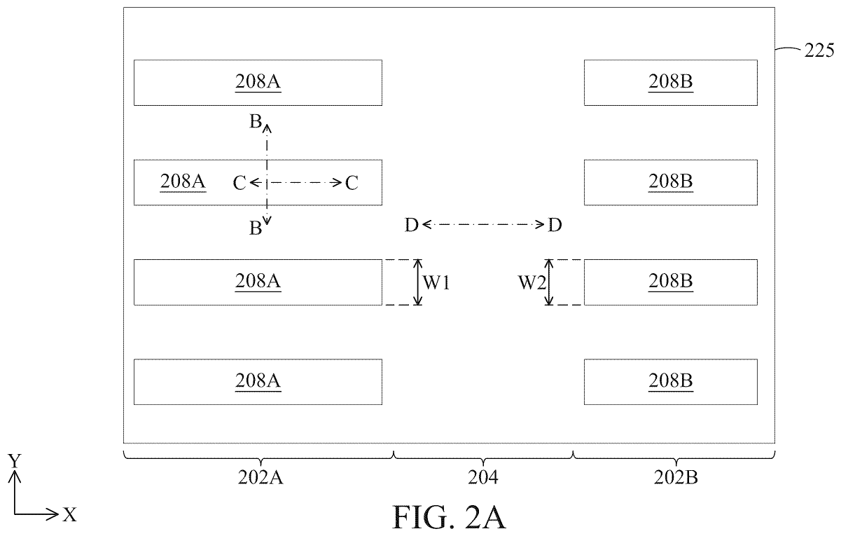

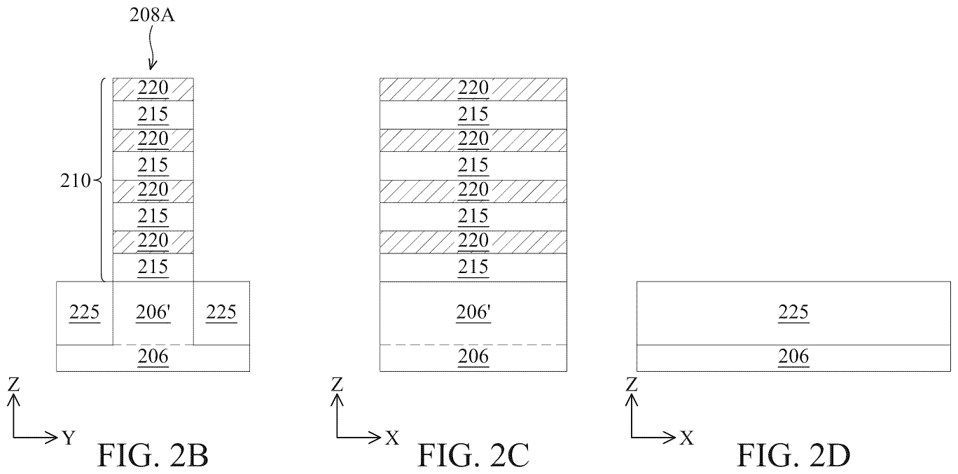

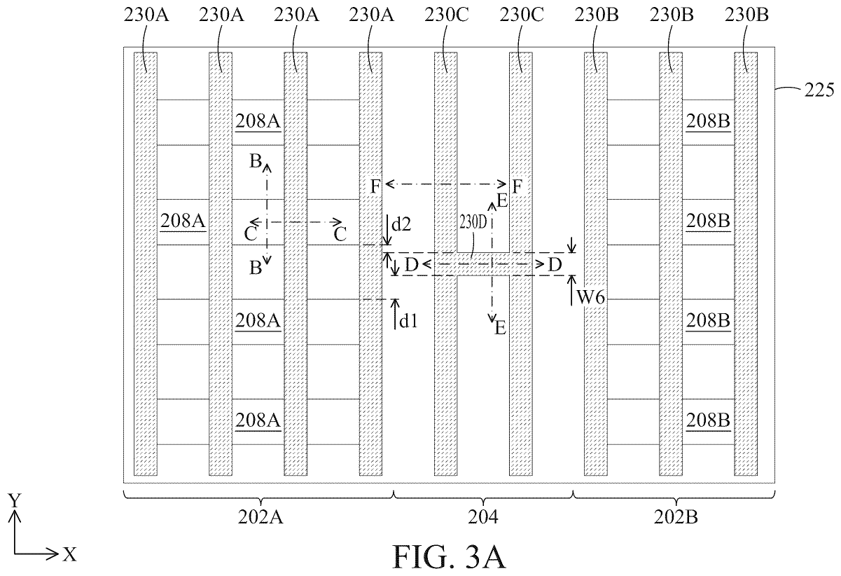

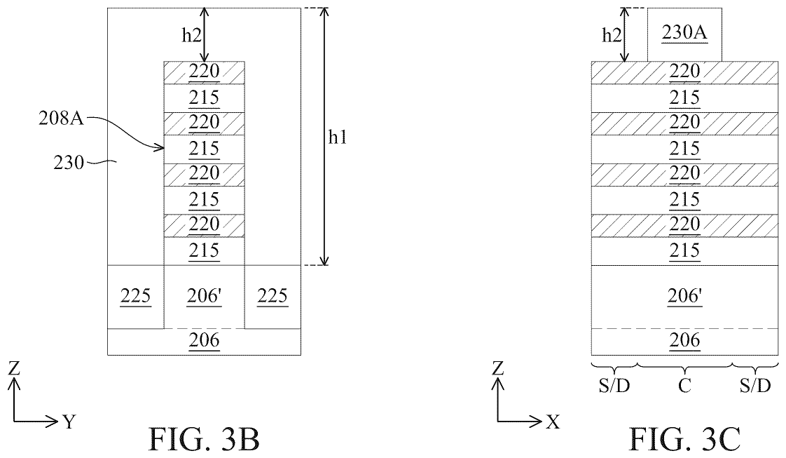

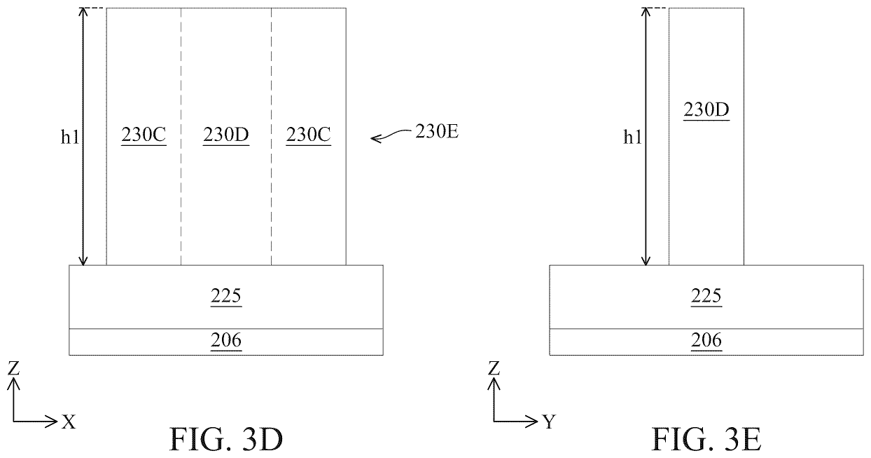

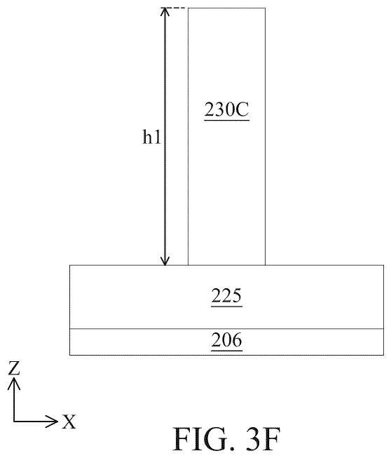

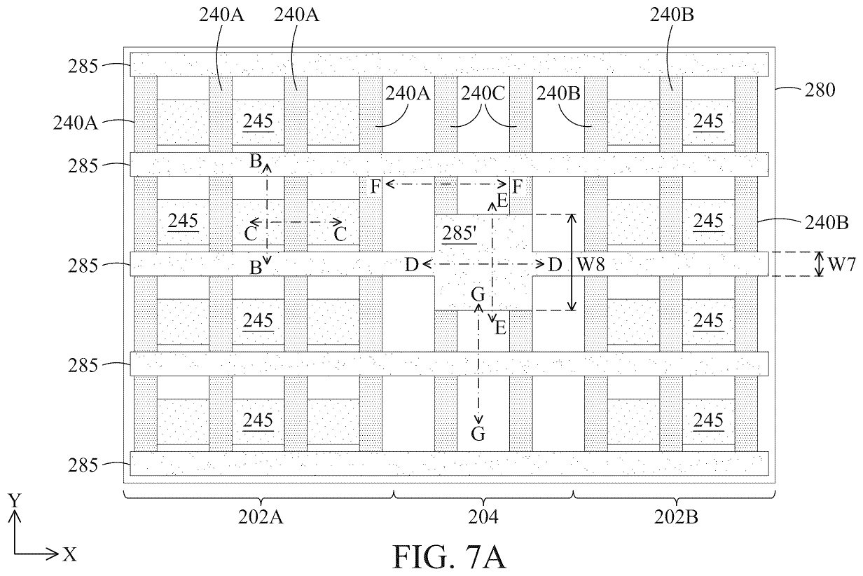

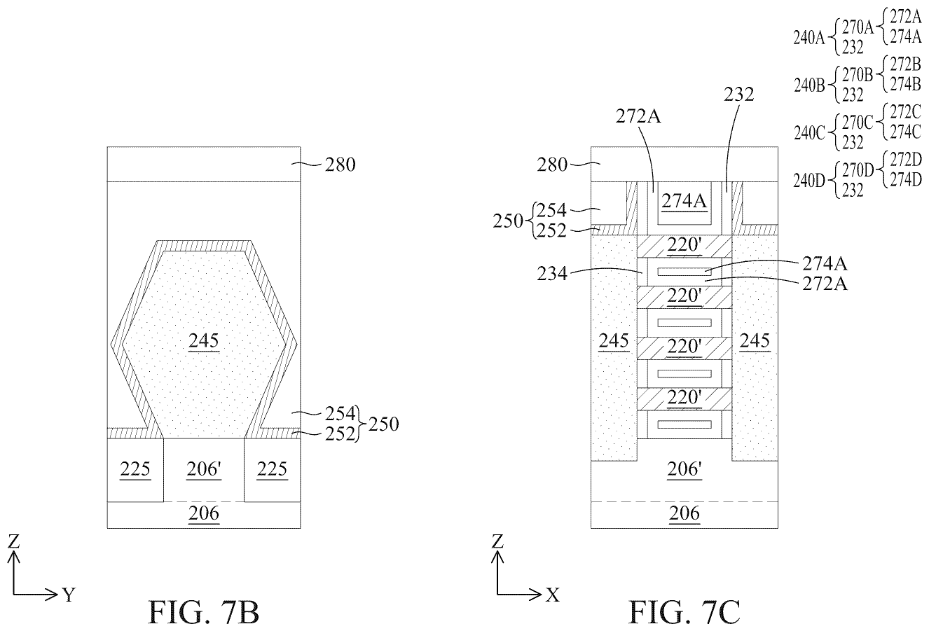

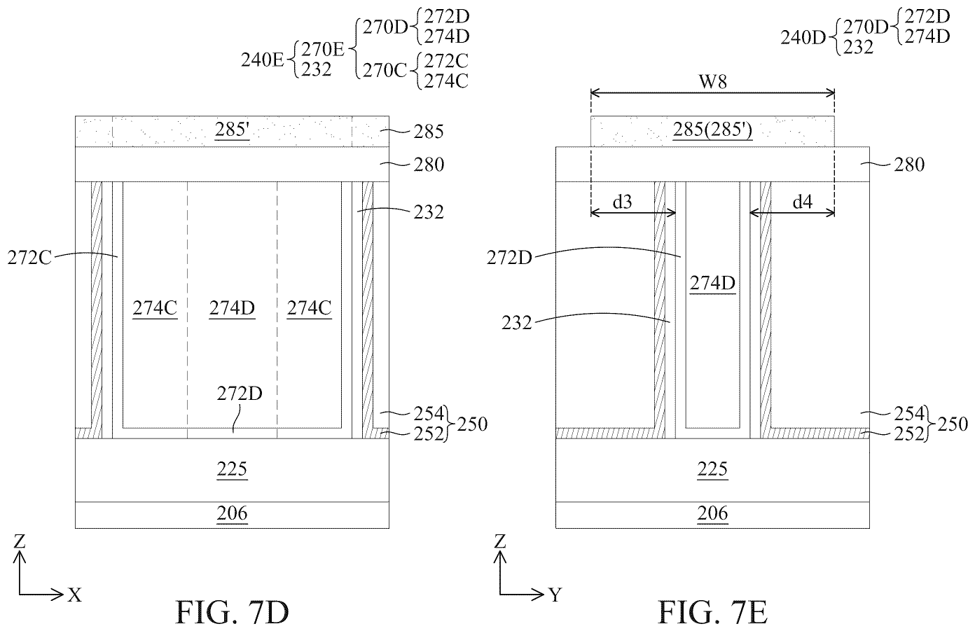

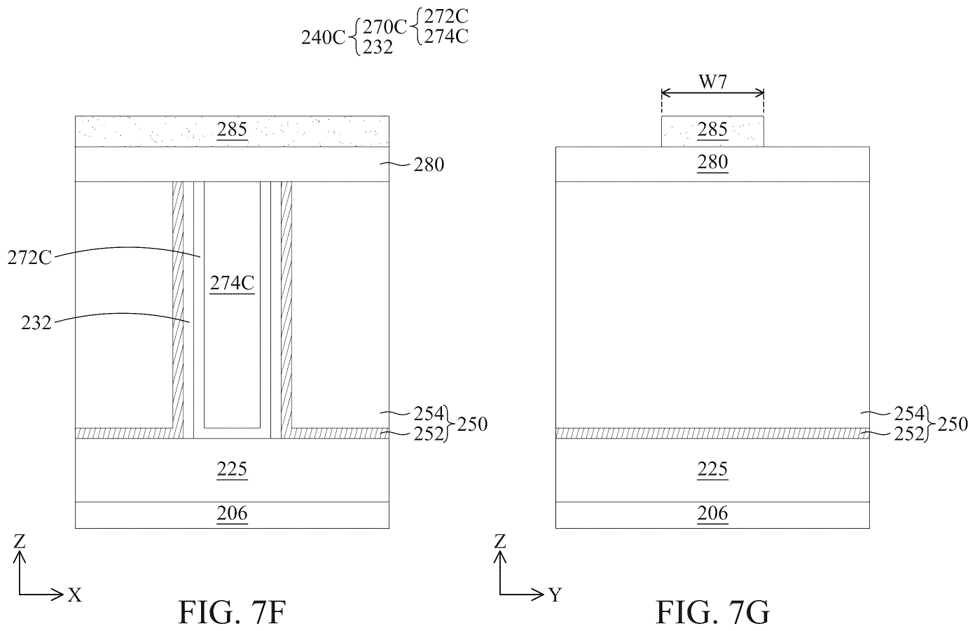

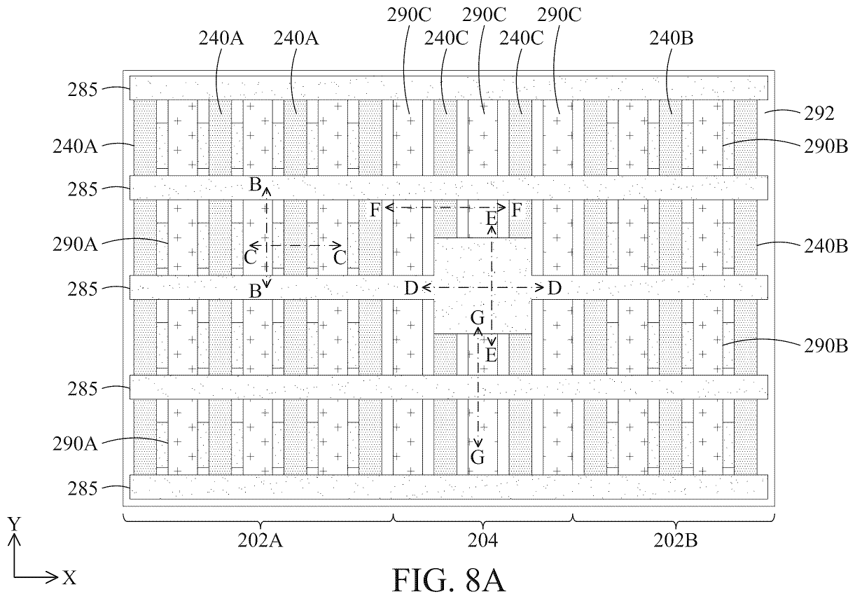

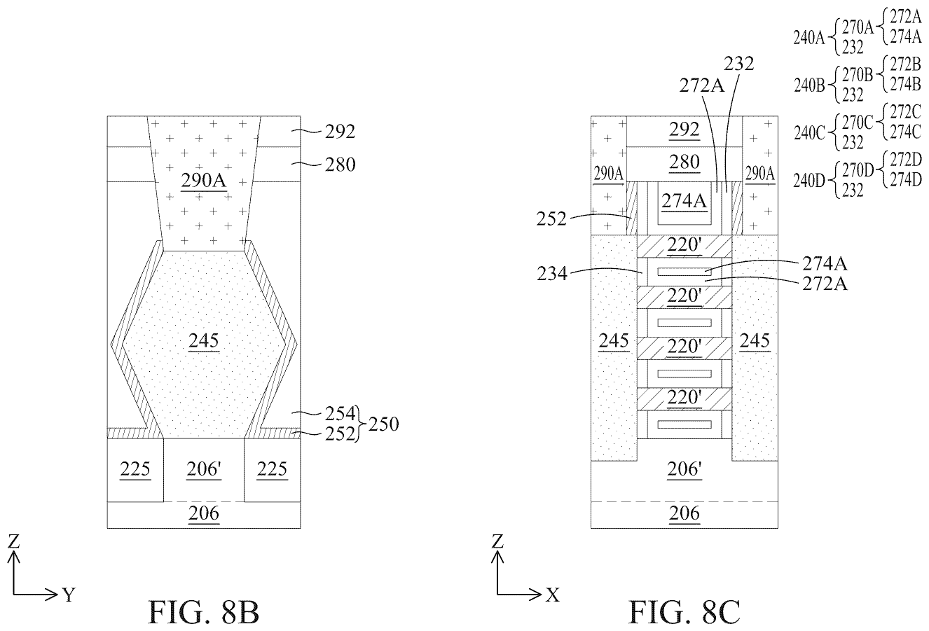

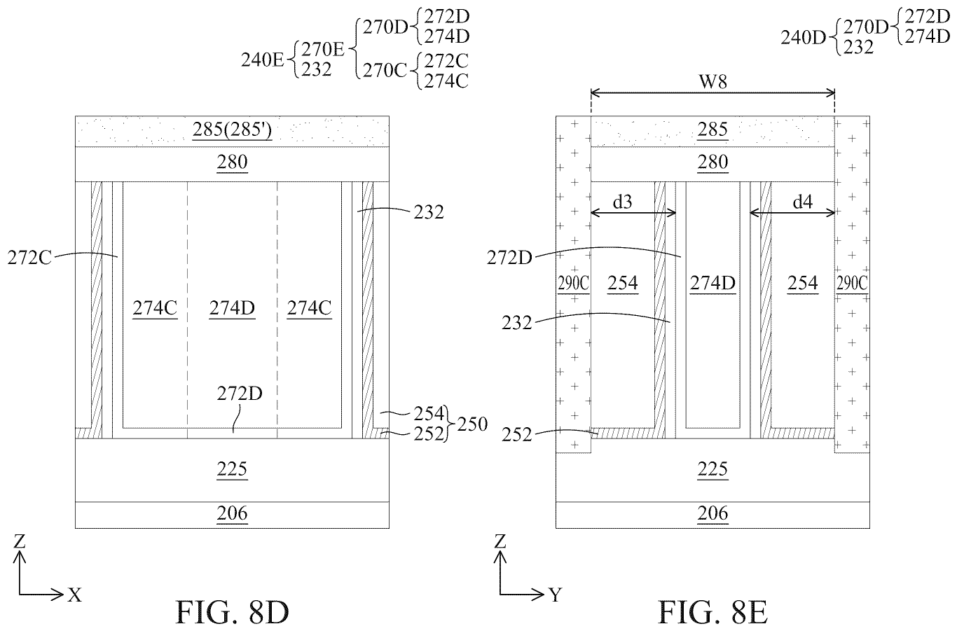

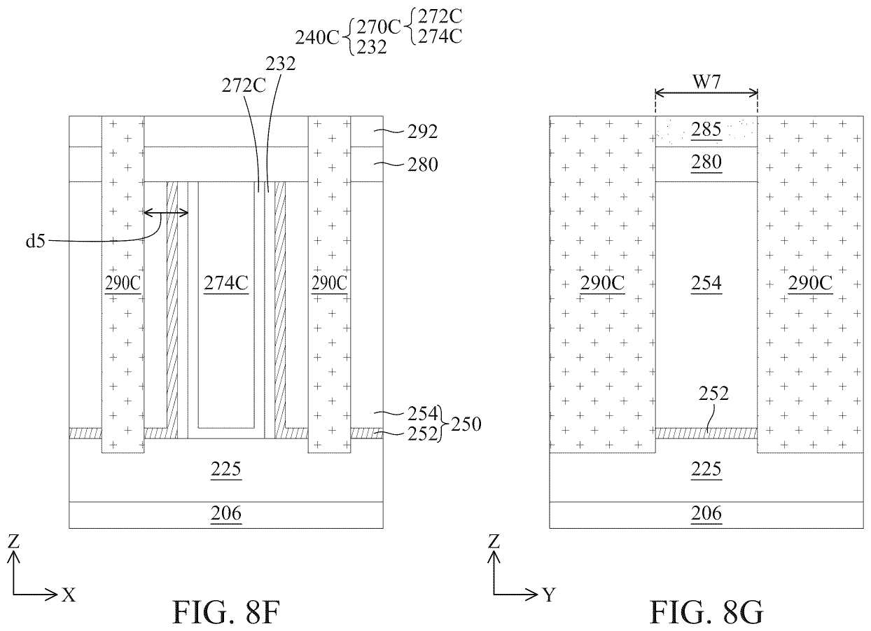

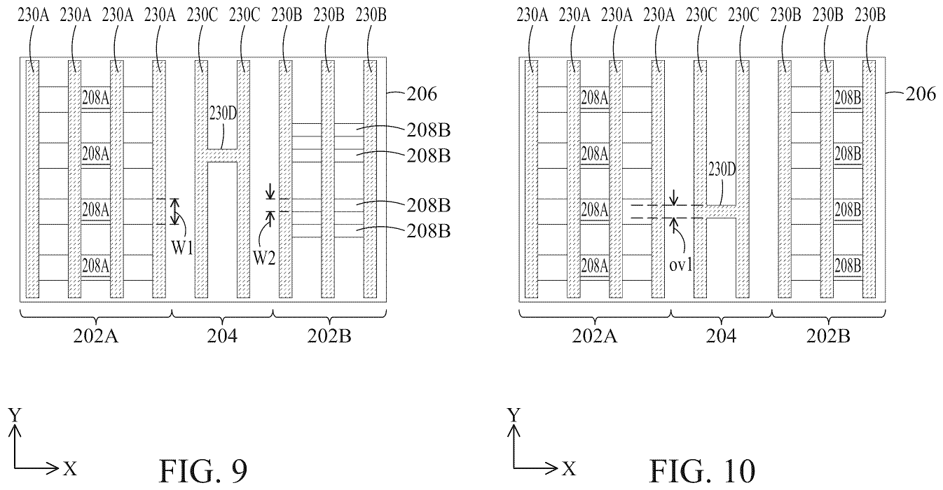

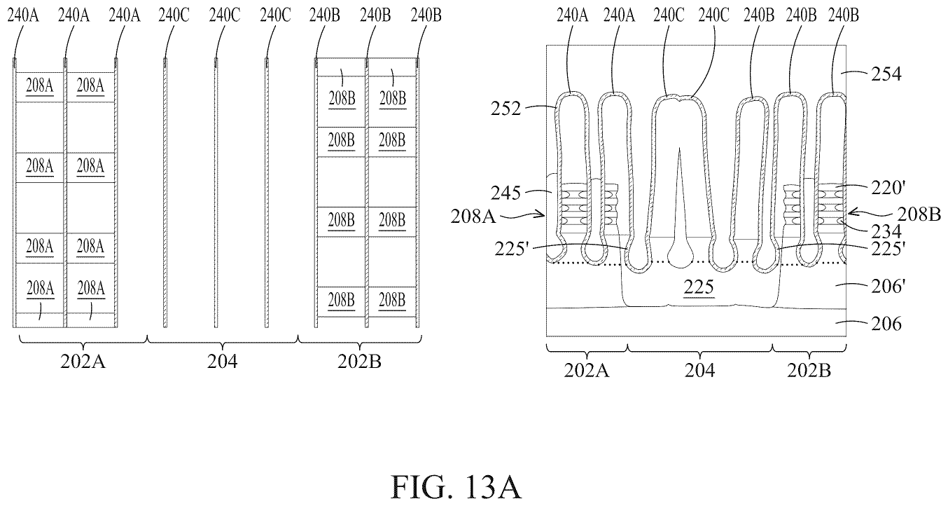

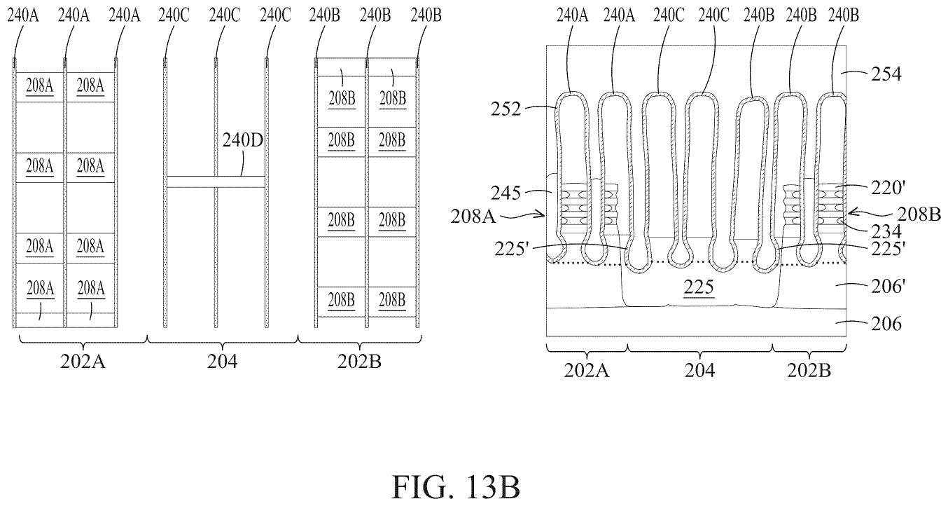

FIGS. 2A-8A are top views of a device 200, in portion or entirety, at various fabrication stages (such as those associated with method 100 in FIG. 1) according to various aspects of the present disclosure. FIGS. 2B-8B are cross-sectional views (e.g., y-cuts) of device 200, in portion or entirety, along lines B-B of FIGS. 2A-8A, respectively, according to various aspects of the present disclosure. FIGS. 2C-8C are cross-sectional views (e.g., x-cuts) of device 200, in portion or entirety, along lines C-C of FIGS. 2A-8A, respectively, according to various aspects of the present disclosure. FIGS. 2D-8D are cross-sectional views (e.g., x-cuts) of device 200 along lines D-D of FIGS. 2A-8A, respectively, according to various aspects of the present disclosure. FIGS. 3E-8E are cross-sectional views (e.g., y-cuts) of device 200, in portion or entirety, along lines E-E of FIGS. 3A-8A, respectively, according to various aspects of the present disclosure. FIGS. 3F-8F are cross-sectional views (e.g., x-cuts) of device 200, in portion or entirety, along lines F-F of FIGS. 3A-8A, respectively, according to various aspects of the present disclosure. FIG. 7G and FIG. 8G are cross-sectional views (e.g., x-cuts) of device 200, in portion or entirety, along lines G-G of FIG. 7A and FIG. 8A, respectively, according to various aspects of the present disclosure. FIGS. 9-12 are different top views of device 200, in portion or entirety, after undergoing processing associated with FIGS. 2A-2D and FIGS. 3A-3D according to various aspects of the present disclosure. FIG. 13A provides a top view and a cross-sectional view of device 200, in portion or entirety, without gate support structures, according to various aspects of the present disclosure. FIG. 13B provides a top view and a cross-sectional view of device 200, in portion or entirety, with gate support structures, according to various aspects of the present disclosure. FIGS. 2A-8A, FIGS. 2B-8B, FIGS. 2C-8C, FIGS. 2D-8D, FIGS. 3E-8E, FIGS. 3F-8F, FIGS. 7G-8G, FIGS. 9-12, FIG. 13A, and FIG. 13B are discussed concurrently herein for ease of description and understanding and have been simplified for the sake of clarity to better understand the inventive concepts of the present disclosure. Additional features may be added in device 200, and some of the features described below may be replaced, modified, or eliminated in other embodiments of device 200.

Device 200 may include a device region 202A, a device region 202B, and an isolation region 204 between device region 202A and device region 202B. As described herein, device 200 may be processed to form transistors, such as GAA transistors, in device region 202A and device region 202B. In some embodiments, device region 202A is processed to form n-type GAA transistors therein, and device region 202B is processed to form p-type GAA transistors therein, or vice versa. In some embodiments, device region 202A and/or device region 202B is processed to form both n-type GAA transistors and p-type GAA transistors therein. In such embodiments, device region 202A and device region 202B may include complementary metal-oxide semiconductor (CMOS) transistor. Isolation region 204 is configured to electrically isolate device region 202A and device region 202B. For example, isolation region 204 may electrically isolate transistors of device region 202A from transistors of device region 202B.

Referring to FIGS. 2A-2D, a fin fabrication process may be performed to form fins extending from a substrate (wafer) 206, such as fins 208A and fins 208B (also referred to as fin structures, fin elements, etc.) extending from substrate 206. Fins 208A are disposed in device region 202A, and fins 208B are disposed in device region 202B. Fins 208A and fins 208B extend substantially parallel to one another along an x-direction, having a length in the x-direction, a width in a y-direction, and a height in a z-direction. For example, fins 208A have a width W1, and fins 208B have a width W2. In the depicted embodiment, fins 208A and fins 208B have the same width (i.e., width W1 is the same as width W2), and fins 208A are middle-aligned with fins 208B along the x-direction. Fins 208A and fins 208B are thus aligned and/or overlap along the x-direction. In some embodiments, fins 208A and fins 208B have different widths (i.e., width W1 is greater than or less than width W2), and fins 208A are middle-aligned, top-aligned, or bottom-aligned with fins 208B along the x-direction. In some embodiments, referring to FIG. 9, width W2 is less than width W1, some fins 208B are aligned with and/or overlap fins 208A, and some fins 208B are not aligned with and do not overlap fins 208A. For example, in FIG. 9, topmost fin 208B and bottommost fin 208B are not aligned with and do not overlap a respective fin 208A, one of middle fins 208B is middle-aligned with and overlaps a respective fin 208A, and one of middle fins 208B is top-aligned with and overlaps a respective fin 208A. In some embodiments, one or more of fins 208B may overlap a respective fin 208A without being middle-aligned, top-aligned, or bottom-aligned therewith. The present disclosure contemplates various alignment and/or width configurations of fins 208A and fins 208B.

Referring again to FIGS. 2A-2D, each of fins 208A and fins 208B include a substrate portion and a semiconductor layer stack portion disposed over the substrate portion. The substrate portion includes a mesa 206′ (also referred to as a substrate extension, a fin portion of substrate 206, a substrate fin portion, an etched substrate portion, etc.). In the depicted embodiment, substrate 206 includes silicon. Substrate 206 may alternatively or additionally include another elementary semiconductor, such as germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 206 is a semiconductor-on-insulator substrate, such as a silicon-on-insulator substrate, a silicon germanium-on-insulator substrate, or a germanium-on-insulator substrate. Substrate 206 (including mesas 206′) may include various doped regions, such as p-wells and n-wells. The n-wells are doped with n-type dopants, such as phosphorus, arsenic, other n-type dopant, or combinations thereof. The p-wells are doped with p-type dopants, such as boron, indium, other p-type dopant, or combinations thereof. In some embodiments, substrate 206 includes doped regions formed with a combination of p-type dopants and n-type dopants. The various doped regions may be formed directly on and/or in substrate 206, for example, providing a p-well structure, an n-well structure, a dual-well structure, a raised structure, or combinations thereof. An ion implantation process, a diffusion process, and/or other suitable doping process may be performed to form the various doped regions.

The semiconductor layer stack portion includes a semiconductor layer stack 210 having semiconductor layers 215 and semiconductor layers 220. Each semiconductor layer stack 210 is disposed over a respective mesa 206′ of substrate 206 and includes respective semiconductor layers 215 and respective semiconductor layers 220. Semiconductor layers 215 and semiconductor layers 220 are stacked vertically (e.g., along the z-direction) in an interleaving or alternating configuration from a top surface of substrate 206. A composition of semiconductor layers 215 and a composition of semiconductor layers 220 are different to achieve etching selectivity and/or different oxidation rates during processing. For example, semiconductor layers 215 and semiconductor layers 220 include different materials, constituent atomic percentages, constituent weight percentages, thicknesses, other characteristics, or combinations thereof to achieve desired etching selectivity. In the depicted embodiment, semiconductor layers 220 include silicon, and semiconductor layers 215 include silicon germanium. With such compositions, semiconductor layers 215 may have a first etch rate to an etchant, and semiconductor layers 220 may have a second etch rate to the etchant, where the first etch rate and the second etch rate are different. In some embodiments, semiconductor layers 220 include silicon germanium having a germanium atomic percent that is different than a germanium atomic percent of semiconductor layers 215. In some embodiments, semiconductor layers 215 and/or semiconductor layers 220 include n-type dopants and/or p-type dopants. The present disclosure contemplates semiconductor layers 215 and semiconductor layers 220 having any combination of semiconductor materials that provide desired etching selectivity and/or desired performance characteristics (e.g., materials that maximize current flow).

As described further below, semiconductor layers 220 or portions thereof form channel regions of transistors in device 200. In FIGS. 2A-2D, each semiconductor layer stack 210 includes four semiconductor layers 215 and four semiconductor layers 220. Semiconductor layer stack 210 thus includes four semiconductor layer pairs disposed over substrate 206, each of which has a respective semiconductor layer 215 and a respective semiconductor layer 220. After processing, this configuration may result in transistors of device 200 having four channels. In some embodiments, semiconductor layer stack 210 includes more or less semiconductor layers depending, for example, on a number of channels desired for and/or design requirements of transistors of device 200. For example, semiconductor layer stack 210 may include two to ten semiconductor layers 220. Thicknesses of semiconductor layers 215 and semiconductor layers 220 may be chosen based on fabrication and/or device performance considerations. For example, thickness of semiconductor layers 215 are configured to provide a desired distance (or spacing) between adjacent channels (e.g., between semiconductor layers 220), and thickness of semiconductor layers 220 are configured to provide a desired thickness of channels.

Fabrication of fins 208A and fins 208B may include forming a semiconductor layer stack precursor over substrate 206 and performing a lithography process and/or an etching process to pattern the semiconductor layer stack precursor and/or substrate 206. In some embodiments, forming the semiconductor layer stack precursor includes epitaxially growing semiconductor layers 215 and semiconductor layers 220 in an interleaving and alternating configuration over substrate 206. For example, a first one of semiconductor layers 215 is epitaxially grown on substrate 206, a first one of semiconductor layers 220 is epitaxially grown on the first one of semiconductor layers 215, a second one of semiconductor layers 215 is epitaxially grown on the first one of semiconductor layers 220, and so on until a desired number of semiconductor layers 215 and semiconductor layers 220 are provided for semiconductor layer stack 210. Epitaxial growth may be achieved by a molecular beam epitaxy (MBE) process, a chemical vapor deposition (CVD) process, a metalorganic chemical vapor deposition (MOCVD) process, other suitable epitaxial growth process, or combinations thereof.

The lithography process may include forming a resist layer over the semiconductor layer stack precursor (for example, by spin coating), performing a pre-exposure baking process, performing an exposure process using a mask, performing a post-exposure baking process, and performing a developing process. During the exposure process, the resist layer is exposed to radiation energy (such as ultraviolet (UV) light, deep UV (DUV) light, or extreme UV (EUV) light), where the mask blocks, transmits, and/or reflects radiation to the resist layer depending on a mask pattern of the mask and/or mask type (for example, binary mask, phase shift mask, or EUV mask), such that an image is projected onto the resist layer that corresponds with the mask pattern. Since the resist layer is sensitive to radiation energy, exposed portions of the resist layer chemically change, and exposed (or non-exposed) portions of the resist layer are dissolved during the developing process depending on characteristics of the resist layer and characteristics of a developing solution used in the developing process. After development, the patterned resist layer includes a resist pattern that corresponds with the mask. The etching process removes portions of the semiconductor layer stack precursor and/or substrate 206 using the patterned resist layer as an etch mask. In some embodiments, the patterned resist layer is formed over a mask layer disposed over the semiconductor layer stack precursor, a first etching process removes portions of the mask layer to form a patterning layer (e.g., a patterned hard mask layer), and a second etching process removes portions of the semiconductor layer stack precursor and/or substrate 206 using the patterning layer as an etch mask. The etching process is a dry etch, a wet etch, other suitable etching process, or combinations thereof. In some embodiments, the etching process is a reactive ion etching (RIE) process. After etching, the patterned resist layer may be removed, for example, by a resist stripping process or other suitable process.

In some embodiments, fins 208A and fins 208B are formed by a multiple patterning process, such as a double patterning lithography (DPL) process (for example, a lithography-etch-lithography-etch (LELE) process, a self-aligned double patterning (SADP) process, a spacer-is-dielectric (SID) process, other double patterning process, or combinations thereof), a triple patterning process (for example, a lithography-etch-lithography-etch-lithography-etch (LELELE) process, a self-aligned triple patterning (SATP) process, other triple patterning process, or combinations thereof), other multiple patterning process (for example, a self-aligned quadruple patterning (SAQP) process), or combinations thereof. Such processes may also provide each of fins 208A and fins 208B with a respective semiconductor layer stack 210 over a respective mesa 206′. In some embodiments, directed self-assembly (DSA) techniques are implemented while patterning the semiconductor layer stack precursor. Further, in some embodiments, the exposure process may implement maskless lithography, electron-beam (e-beam) writing, ion-beam writing, or combinations thereof for patterning the resist layer.

Substrate isolation structures 225 may be formed over substrate 206 after forming fins 208A and fins 208B. Substrate isolation structures 225 may fill lower portions of trenches between fins 208A, fins 208B, and fins 208A and fins 208B. Substrate isolation structures 225 may surround portions of fins 208A and fins 208B, and portions of fins 208A and fins 208B that extend beyond top surfaces of substrate isolation structures 225 may be referred to as fin active regions. Substrate isolation structures 225 electrically isolate active device regions and/or passive device regions. For example, substrate isolation structures 225 separate and electrically isolate fins 208A, fins 208B, and fins 208A and fins 208B (e.g., fins 208A are isolated from fins 208B by a respective one of substrate isolation structures 225 that spans isolation region 204). Substrate isolation structures 225 include silicon oxide, silicon nitride, silicon oxynitride, other suitable isolation material (including, for example, silicon, oxygen, nitrogen, carbon, other suitable isolation constituent, or combinations thereof), or combinations thereof. Substrate isolation structures 225 may have a multilayer structure. For example, substrate isolation structures 225 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 225 may include a bulk dielectric over a doped liner, such as a boron silicate glass (BSG) liner and/or a phosphosilicate glass (PSG) liner. Dimensions and/or characteristics of substrate isolation structures 225 are configured to provide shallow trench isolation (STI) structures, deep trench isolation (DTI) structures, local oxidation of silicon (LOCOS) structures, other suitable isolation structures, or combinations thereof. For example, substrate isolation structures 225 may be STIs.

Substrate isolation structures 225 may be formed by depositing a liner layer (e.g., a dielectric layer) over device 200 that partially fills trenches between fins, depositing an oxide material over device 200 (e.g., over the liner layer) that fills remainders of the trenches, and performing a planarization process. The planarization process, such as a chemical mechanical polishing (CMP) process, may be performed until reaching and exposing a planarization stop layer, such as top semiconductor layers 220. In some embodiments, the planarization process removes mask layers, any of the liner layer, any of the oxide material, or combinations thereof that are above and/or over top surfaces of fins 208A and fins 208B. Remainders of the liner layer and the oxide material form liners and bulk dielectrics, respectively, of substrate isolation structures 225. The liner may cover sidewalls of the trenches (formed by sidewalls of the fins) and bottoms of the trenches (formed by substrate 206). The liner layer may be formed by atomic layer deposition (ALD), CVD, physical vapor deposition (PVD), or combinations thereof. The oxide material may be formed by flowable CVD (FCVD), a high aspect ratio deposition (HARP) process, high density plasma CVD (HDPCVD), or combinations thereof. In some embodiments, an annealing process is performed when forming substrate isolation structures 225.

Substrate isolation structures 225 may then be recessed and/or etched back, such that fins 208A and fins 208B protrude from substrate isolation structures 225. In FIGS. 2A-2D, substrate isolation structures 225 are etched back until below semiconductor layer stacks 210. In some embodiments, a height of substrate isolation structures 225 is less than or equal to a height of mesas 206′ (e.g., relative to a top surface of substrate 206). In some embodiments, an etching process selectively removes substrate isolation structures 225 with respect to semiconductor layer stacks 210. For example, the etching process etches/removes substrate isolation structures 225 with no to negligible etching/removal of semiconductor layers 220, semiconductor layers 215, and mesas 206′. An etchant may be selected for the etching process that etches dielectric materials at a higher rate than semiconductor materials. The etching process is a dry etch, a wet etch, other suitable etch, or combinations thereof. In some embodiments, the etching process removes mask/patterning layers of fins 208A and/or fins 208B. In some embodiments, the mask/patterning layers function as etch masks during the etching process.

Referring to FIGS. 3A-3F, dummy gates 230A are formed over portions of fins 208A in device region 202A, dummy gates 230B are formed over portions of fins 208B in device region 202B, and dummy gates 230C are formed over substrate isolation structure 225 in isolation region 204. Dummy gates 230A-230C extend lengthwise in a direction that is different than (e.g., orthogonal to) the lengthwise direction of fins 208A and fins 208B. For example, dummy gates 230A-230C extend substantially parallel to one another along the y-direction, having a length in the y-direction, a width in the x-direction, and a height in the z-direction. Dummy gates 230A may have a width W3, dummy gates 230B may have a width W4, and dummy gates 230C may have a width W5. Each of width W3, width W4, and width W5 may be less than widths of the active regions (e.g., less than width W1 of fins 208A and/or width W2 of fins 208B). In the depicted embodiment, width W3, width W4, and width W5 are the same. In some embodiments, width W3, width W4, width W5, or combinations thereof are different. For example, width W5 may be different than (e.g., less than or greater than) width W3 and/or width W4 (i.e., widths of dummy gates in device regions are different than widths of dummy gates in isolation regions). In another example, width W3 is different than (e.g., less than or greater than) width W4 (i.e., different device regions have different dummy gate widths).

Along the fin widthwise direction (see, e.g., FIG. 3B), dummy gates 230A are disposed on tops and sidewalls of fins 208A, dummy gates 230A wrap channel regions (C) of fins 208A, and dummy gates 230A are disposed over tops of substrate isolation structures 225. Further, dummy gates 230B are disposed on tops and sidewalls of fins 208B, dummy gates 230B wrap channel regions of fins 208B, and dummy gates 230B are disposed over tops of substrate isolation structures 225. Along the fin lengthwise direction (see, e.g., FIG. 3C), dummy gates 230A are disposed over tops of respective channel regions of fins 208A, and dummy gates 230A are disposed between respective source/drain regions (S/D) of fins 208A. Further, dummy gates 230B are disposed over tops of respective channel regions of fins 208B, and dummy gates 230B are disposed between respective source/drain regions of fins 208B. Because dummy gates in the device region 202A and device region 202B are formed over both fins and substrate isolation structures, the dummy gates in device region 202A and device region 202B may have varying heights. For example, dummy gates 230A and dummy gates 230B may have a height h2 over fins 208A and fins 208B, respectively, and a height h1 over substrate isolation structures 225. Height h1 is between top surfaces of substrate isolation structures 225 and top surfaces of dummy gates 230A, 230B, height h2 is between top surfaces of fins 208A, 208B and top surfaces of dummy gates 230A, 230B, and height h2 is less than height h1.

Dummy gates 230C are disposed over tops of substrate isolation structures 225 along the fin widthwise direction and the fin lengthwise direction (see, e.g., FIG. 3D). To hinder peeling and/or collapsing of dummy gates 230C in isolation region 204, gate support structures are inserted in isolation region 204 between dummy gates 230C. For example, dummy gates are formed over substrate isolation structure 225 in isolation region 204 that extend along the fin lengthwise direction (e.g., the x-direction) to connect at least two dummy gates 230C. In the depicted embodiment, a dummy gate 230D extends lengthwise along the x-direction and connects two dummy gates 230C, such that dummy gate 230D has a length in the x-direction, a width in the y-direction, and a height in the z-direction. Dummy gate 230D may have a width W6, and dummy gate 230D may have height h1. In the depicted embodiment, width W6 is the same as width W4, width W5, and width W3. In some embodiments, width W6 is different than width W5, width W4, width W3, or combinations thereof. For example, to increase structural support of dummy gates 230C, width W6 may be greater than width W5.

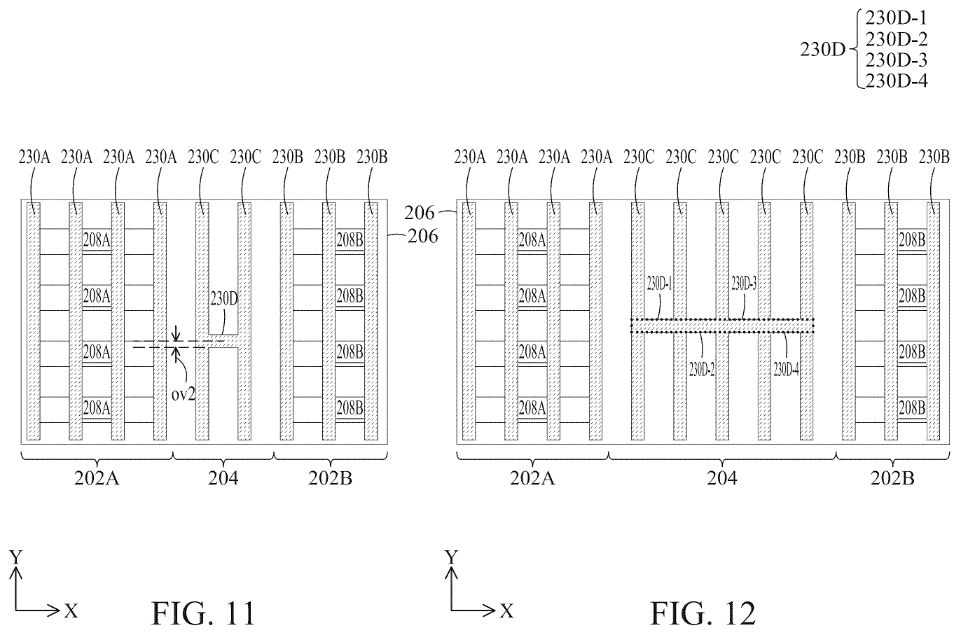

In the depicted embodiment, dummy gate 230D is not aligned with and does not overlap active regions of the device regions. Dummy gate 230D may thus be shifted a distance away from active regions along the y-direction, such as a distance d1 between dummy gate 230D and a respective fin along the y-direction (e.g., a respective fin 208A and/or a respective fin 208B) and a distance d2 between dummy gate 230D and another respective fin along the y-direction (e.g., a respective fin 208A and/or a respective fin 208B). In some embodiments, dummy gate 230D is middle-aligned, top-aligned, or bottom-aligned with fins 208A and/or fins 208B along the x-direction. For example, referring to FIG. 10, dummy gate 230D may be middle-aligned with both fins 208A and fins 208B, such as where fins 208A and fins 208B are middle-aligned, and dummy gate 230D has an overlap ov1 with fins 208A and/or fins 208B. In FIG. 10, where width W6 is less than width W1 and/or width W2, overlap ov1 is equal to width W6. In embodiments where width W6 is greater than width W1 and/or width W2, overlap ov1 is equal to width W1 and/or width W2. In another example, referring to FIG. 11, dummy gate 230D may overlap respective fins 208A and/or respective fins 208B without being middle-aligned, top-aligned, or bottom-aligned therewith. In FIG. 11, dummy gate 230D has an overlap ov2 with fins 208A and/or fins 208B and overlap ov2 is less than width W6. In some embodiments, dummy gate 230D is middle-aligned, top-aligned, or bottom-aligned with fins 208A, but not fins 208B. In such embodiments, dummy gate 230D may overlap fins 208A, and dummy gate 230D may or may not overlap fins 208B. The present disclosure contemplates various alignment and/or width configurations of dummy gate 230D.

In some embodiments, more than one dummy gate 230D connects the two dummy gates 230C. In some embodiments, dummy gate 230D connects more than two dummy gates 230C, such as two to six dummy gates 230C. For example, referring to FIG. 12, five dummy gates 230C, instead of two, may extend lengthwise along the y-direction in isolation region 204, and dummy gate 230D may extend lengthwise along the x-direction to connect the five dummy gates 230C. In such example, dummy gate 230D may be formed from a dummy gate 230D-1, a dummy gate 230D-2, a dummy gate 230D-3, a dummy gate 230D-4, and portions of dummy gates 230C that are merged together by dummy gates 230D-1-230D-4. Each of dummy gates 230D-1-230D-4 connect and/or merge two respective dummy gates 230C together, and each of dummy gates 230D-1-230D-4 may be referred to as a dummy sub-gate.

Dummy gates 230A-230D may also be referred to as dummy gate stacks. In some embodiments, dummy gates 230A-230D include a polysilicon layer, and dummy gates 230A-230D may be referred to as poly gates. Dummy gates 230A-230D may be formed of a single layer (e.g., a polysilicon layer) or multiple layers, such as a dummy gate dielectric, a dummy gate electrode, and a hard mask. The dummy gate dielectric includes a dielectric material, such as silicon oxide, a high-k dielectric material, other suitable dielectric material, or combinations thereof. For example, the dummy gate dielectric is a silicon oxide layer (e.g., an SiO₂ layer). The dummy gate electrode includes a suitable dummy gate material, such as polysilicon, and the hard mask includes a suitable hard mask material, such as silicon nitride. In some embodiments, dummy gates 230A-230D are formed at the same time. For example, dummy gates 230A-230D may be formed by depositing a dummy gate dielectric layer over device 200, depositing a dummy gate electrode layer over the dummy gate dielectric layer, depositing a hard mask layer over the dummy gate electrode layer, and performing a lithography process and an etching process to pattern the hard mask layer, the dummy gate electrode layer, and the dummy gate dielectric layer. Remainders of the hard mask layer, the dummy gate electrode layer, and the dummy gate dielectric layer form dummy gates 230A-230D. In some embodiments, substrate isolation structures 225 may be recessed when patterning the hard mask layer, the dummy gate electrode layer, the dummy gate dielectric layer, or combinations thereof, which may result in substrate isolation structures 225 having isolation mesas 225′ extending therefrom (see, e.g., FIG. 13A and FIG. 13B) and dummy gates 230A-230D may be disposed on isolation mesas 225′. In some embodiments, dummy gates in device regions (e.g., dummy gates 230A and dummy gates 230B) and dummy gates in isolation regions (e.g., dummy gates 230C and dummy gate 230D) are formed at different times (i.e., by separate processes). In some embodiments, dummy gates 230C and dummy gate 230D are formed at different times. In some embodiments, dummy gates 230A and dummy gate 230B are formed at different times. In some embodiments, dummy gates 230A-230D are formed at least partially simultaneously (e.g., using the same depositions processes and/or etching processes but different lithography processes).

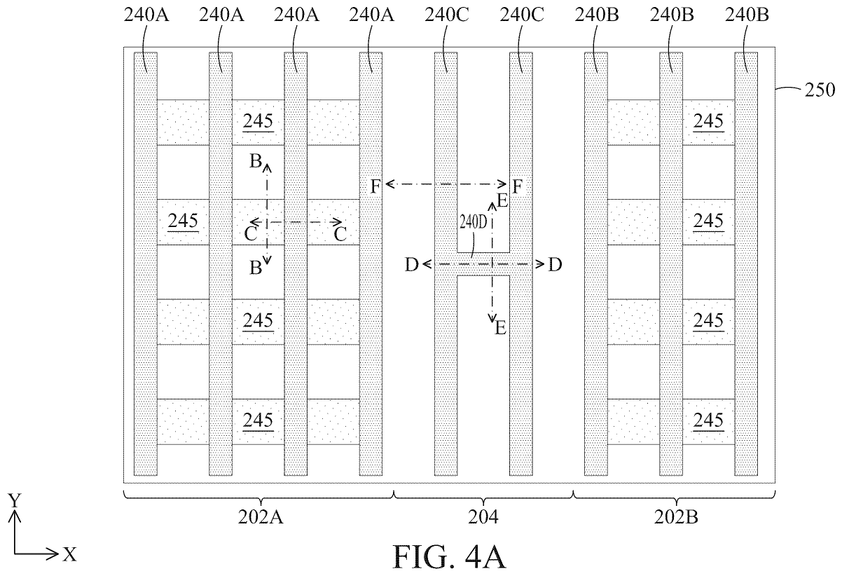

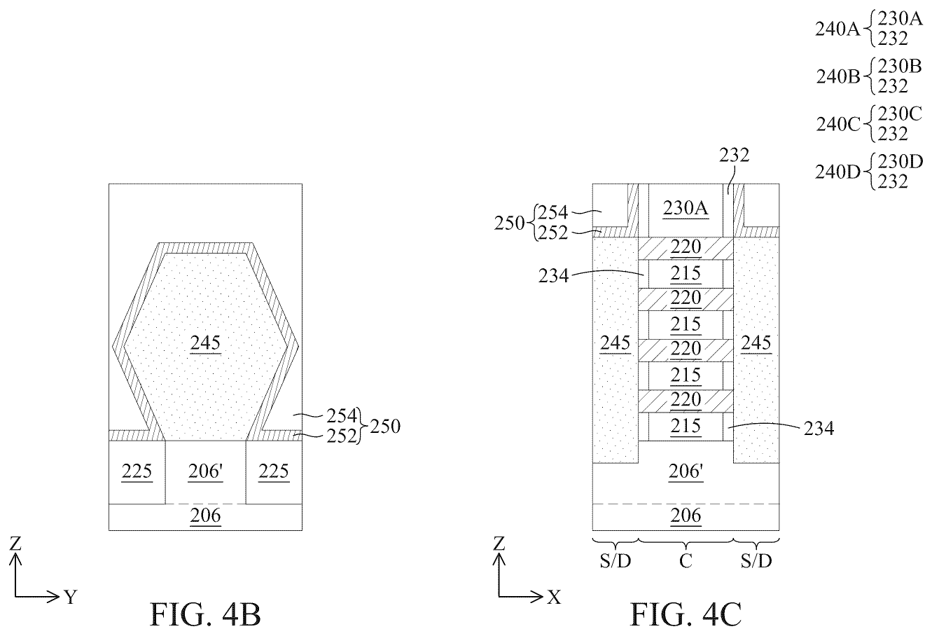

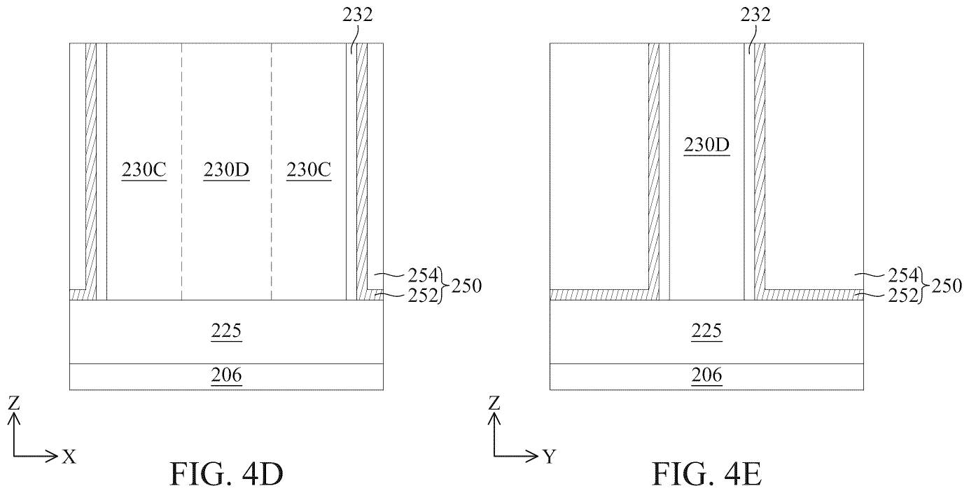

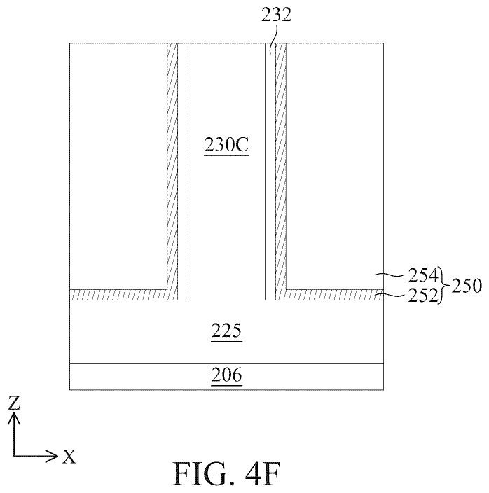

Referring to FIGS. 4A-4F, fabrication of device 200 may include forming gate spacers 232 along sidewalls of dummy gates 230A-230D, thereby forming gate structures 240A-240D. Each of gate structures 240A has a respective dummy gate 230A and gate spacers 232, each of gate structures 240B has a respective dummy gate 230B and gate spacers 232, each of gate structures 240C has a respective dummy gate 230C and gate spacers 232, and gate structure 240D has dummy gate 230D and gate spacers 232. Fin spacers may be formed along sidewalls of source/drain regions of fins 208A and/or fins 208B before, while, or after forming gate spacers 232. Gate spacers 232 are disposed adjacent to dummy gates 230A-230D, and fin spacers may be disposed adjacent to semiconductor layer stacks 210 in source/drain regions of fins 208A and fins 208B before removal thereof. Gate spacers 232 and fin spacers are formed by any suitable process and include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). For example, a spacer layer including silicon and nitrogen, such as a silicon nitride layer, is deposited over device 200 and etched to form gate spacers 232 and fin spacers. In some embodiments, gate spacers 232 and/or fin spacers have a multilayer structure, such as a first dielectric layer that includes silicon nitride and a second dielectric layer that includes silicon carbide. In some embodiments, gate spacers 232 and/or fin spacers include more than one set of spacers, such as seal spacers, offset spacers, sacrificial spacers, dummy spacers, main spacers, or combinations thereof. In such embodiments, the various sets of spacers may have different compositions and/or dimensions.

Fabrication of device 200 may further include partially removing portions of fins 208A and fins 208B (e.g., source/drain regions thereof that are not covered by dummy gates 230A and dummy gates 230B) to form source/drain recesses/trenches, forming inner spacers 234 under gate spacers 232 along sidewalls of semiconductor layers 215, and forming source/drains 245 in the source/drain recesses. Forming the source/drain recesses may include performing an etching process that removes semiconductor stacks 210 in the source/drain regions of fins 208A and fins 208B, thereby exposing mesas 206′ thereof. The etching process may further remove some, but not all, of mesas 206′, such that the source/drain recesses may extend below top surfaces of substrate isolation structures 225. The etching process is a dry etch, a wet etch, other suitable etch, or combinations thereof. In some embodiments, the etching process is a multistep etch process. In some embodiments, parameters of the etching process (e.g., etchant thereof) are configured to selectively remove semiconductor materials (i.e., semiconductor stacks 210) with no to negligible removal of dielectric materials (e.g., hard masks of dummy gates 230A-230D, gate spacers 232, fin spacers, substrate isolation structure 225, etc.). In some embodiments, parameters of the etching process (e.g., etchant thereof) are configured to selectively remove semiconductor materials (i.e., semiconductor stacks 210) with no to negligible removal of polysilicon (e.g., dummy gates 230A-230D) and dielectric materials.

Forming inner spacers 234 may include a first etching process, a deposition process, and a second etching process. The first etching process may selectively etch semiconductor layers 215 with negligible etching of semiconductor layers 220, mesas 206′, substrate isolation structures 225, dummy gates 230A-230D, gate spacers 232, fin spacers, or combinations thereof. The first etching process is configured to laterally etch (e.g., along the x-direction and/or the y-direction) semiconductor layers 215 to form gaps between semiconductor layers 220 and gaps between mesas 206′ and semiconductor layers 220. The first etching process is a dry etch, a wet etch, other suitable etch, or combinations thereof. In some embodiments, the first etching process is an anisotropic etch having a horizontal etch rate greater than a vertical etch rate (e.g., a vertical etch rate of zero), and the anisotropic etch may remove material in substantially the horizontal direction with negligible material removal in the vertical direction.

The deposition process may form an insulation material that fills the gaps between semiconductor layers 220 and the gaps between mesas 206′ and semiconductor layers 220, and the second etching process selectively etches the insulation material to form inner spacers 234 with no to negligible etching of semiconductor layers 220, mesas 206′, substrate isolation structures 225, dummy gates 230A-230D, gate spacers 232, fin spacers, or combinations thereof. To achieve etching selectivity during the second etching process, a composition of the insulation material (and thus inner spacers 234) is different than compositions of semiconductor layers 220, mesas 206′, substrate isolation structure 225, dummy gates 230A-230D, gate spacers 232, or combinations thereof. The insulation material includes a dielectric material that includes silicon, oxygen, carbon, nitrogen, other suitable dielectric constituent, or combinations thereof. For example, the insulation material is silicon nitride, silicon carbonitride, silicon oxycarbonitride, silicon oxycarbide, other suitable material, or combinations thereof. The second etching process is a dry etch, a wet etch, other suitable etch, or combinations thereof.

Source/drains 245 include a semiconductor material, and source/drains 245 may be doped with n-type dopants and/or p-type dopants. In some embodiments (e.g., when forming portions of n-type transistors), source/drains 245 may include silicon doped with carbon, phosphorous, arsenic, other n-type dopant, or combinations thereof (e.g., Si:C source/drains, Si:P source/drains, or Si:C:P source/drains). In some embodiments (e.g., when forming portions of p-type transistors), source/drains 245 may include silicon germanium or germanium doped with boron, other p-type dopant, or combinations thereof (e.g., Si:Ge:B source/drains). In some embodiments, source/drains 245 have a multilayer structure, such as two or more semiconductor layers having different compositions and/or different dimensions/configurations. The different compositions may be achieved by with different semiconductor materials, different dopants, different atomic percentages of constituents, different dopant concentrations, or combinations thereof. In some embodiments, source/drains 245 include materials and/or dopants that achieve desired tensile stress and/or compressive stress in channel regions (e.g., semiconductor layers 220) of transistors formed in device region 202A and/or device region 202B. Source/drains 245 have the same or different compositions and/or materials depending on configurations of their respective transistors. In some embodiments, device region 202A and/or device region 202B include some source/drains 245 configured for n-type transistors (e.g., Si:C source/drains) and some source/drains 245 configured for p-type transistors (e.g., Si:Ge:B source/drains).

Source/drains 245 may be formed by an epitaxy process, which may include epitaxially growing semiconductor material from exposed semiconductor layers 220 and/or mesas 206′. The semiconductor material is formed in and may fill the source/drain recesses. The epitaxy process may use CVD deposition techniques (e.g., remote plasma CVD (RPCVD), low pressure CVD (LPCVD), vapor phase epitaxy (VPE), ultrahigh vacuum CVD (UHV-CVD), or combinations thereof), MBE, other suitable epitaxy process, or combinations thereof. The epitaxy process may use gaseous precursors and/or liquid precursors, which may interact with and/or adsorb on the composition of semiconductor layers 220 and/or mesas 206′, but not interact with compositions of inner spacers 234, gate spacers 232, CESL 252, ILD layer 254, or combinations thereof. In some embodiments, source/drains 245 are doped during deposition (i.e., in-situ), for example, by adding dopant to a source material of the epitaxy process. In some embodiments, source/drains 245 are doped after deposition thereof, for example, by an ion implantation process. In some embodiments, annealing processes (e.g., rapid thermal annealing and/or laser annealing) are performed to activate dopants in source/drains 245. In some embodiments, where source/drains 245 are configured for different transistors and have different compositions and/or materials, source/drains 245 may be formed by separate processing sequences. For example, p-type transistor regions may be masked when forming source/drains 245 for n-type transistors in n-type transistor regions, and n-type transistor regions may be masked when forming source/drains 245 for p-type transistors in p-type transistor regions.

Fabrication of device 200 may further include forming a dielectric layer 250 over device 200, such as over substrate isolation structures 225 and epitaxial source/drains 245. Dielectric layer 250 may fill spaces between adjacent source/drains 245 and spaces between adjacent gate structures 240A-240D. For example, dielectric layer 250 may fill spaces between gate spacers 232 of adjacent gate structures 240A-240D. Forming dielectric layer 250 may include depositing a contact etch stop layer (CESL) 252, depositing an interlayer dielectric (ILD) layer 254 over CESL 252, and performing a CMP and/or other planarization process until reaching (exposing) dummy gates 230A-230D. The planarization process may remove a portion of dummy gates 230A-230D, such as hard masks thereof, to expose underlying dummy gate electrodes thereof, such as polysilicon gates thereof. In such embodiments, heights of dummy gates 230A-230D may be reduced by the planarization process. CESL 252 and ILD layer 254 are formed by CVD, other suitable methods, or combinations thereof. In some embodiments, ILD layer 254 is formed by FCVD, HARP, HDPCVD, or combinations thereof.

ILD layer 254 includes a dielectric material including, for example, silicon oxide, carbon doped silicon oxide, silicon nitride, silicon oxynitride, tetraethyl orthosilicate (TEOS)-formed oxide, BSG, PSG, borophosphosilicate glass (BPSG), fluorosilicate glass (FSG), xerogel, aerogel, amorphous fluorinated carbon, parylene, benzocyclobutene-based (BCB) dielectric material, polyimide, other suitable dielectric material, or combinations thereof. In some embodiments, ILD layer 254 includes a low-k dielectric material having a dielectric constant that is less than a dielectric constant of silicon dioxide (e.g., k<3.9). In some embodiments, ILD layer 254 includes a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or combinations thereof, each of which is tuned/configured to exhibit a dielectric constant less than about 2.5. ILD layer 254 may have a multilayer structure that includes multiple dielectric materials. CESL 252 includes a material different than ILD layer 254, such as a dielectric material that is different than the dielectric material of ILD layer 254. For example, where ILD layer 254 includes a silicon-and-oxygen comprising low-k dielectric material, CESL 252 may include silicon and nitrogen, such as silicon nitride or silicon oxynitride.

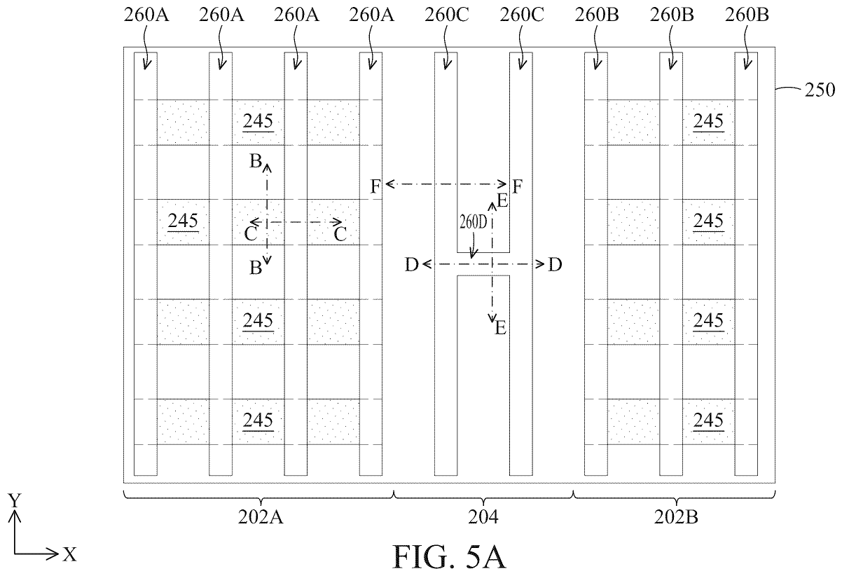

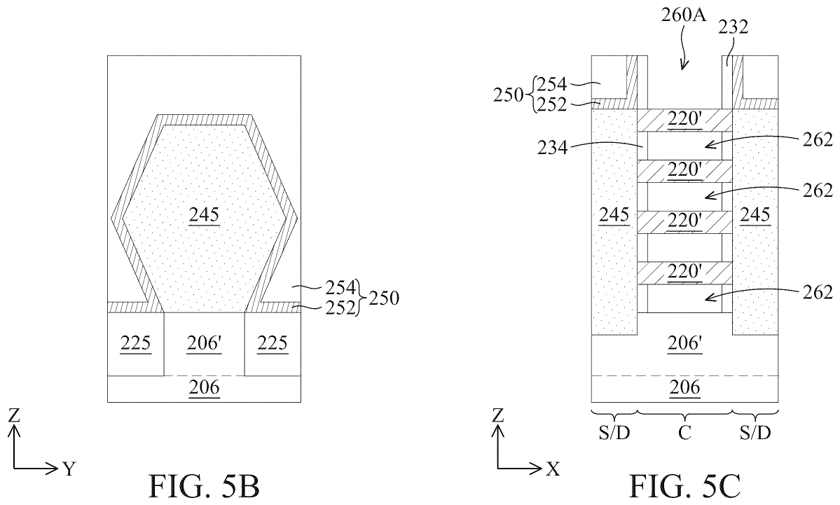

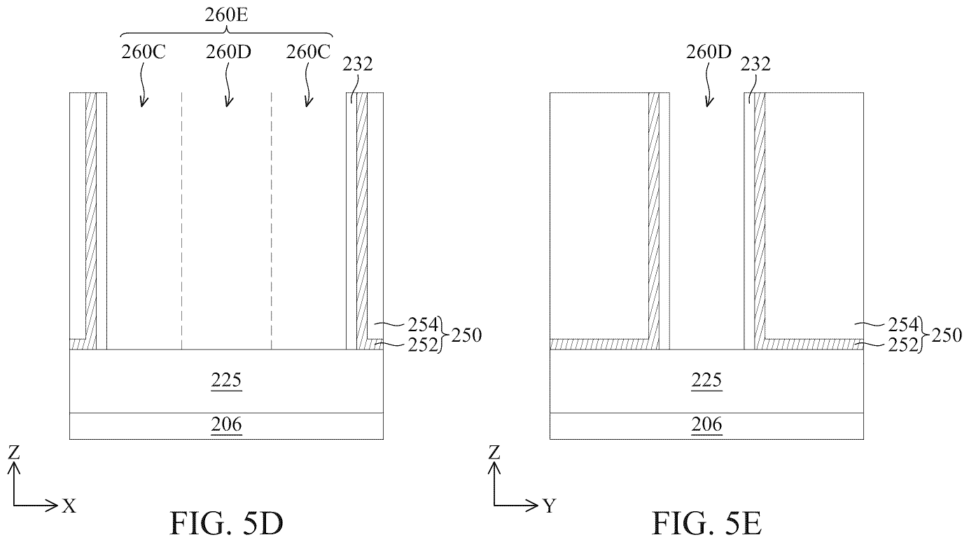

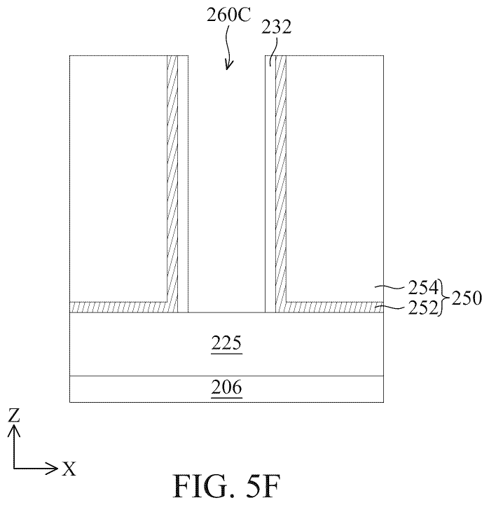

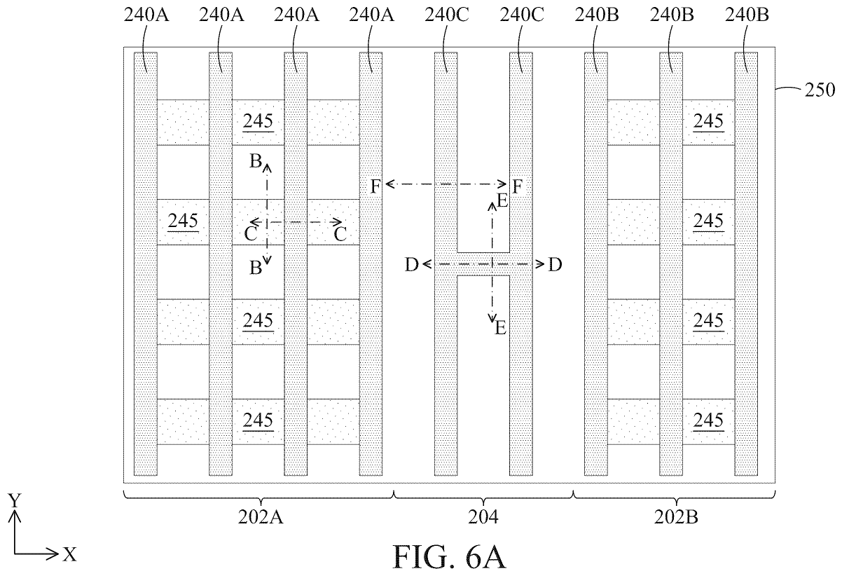

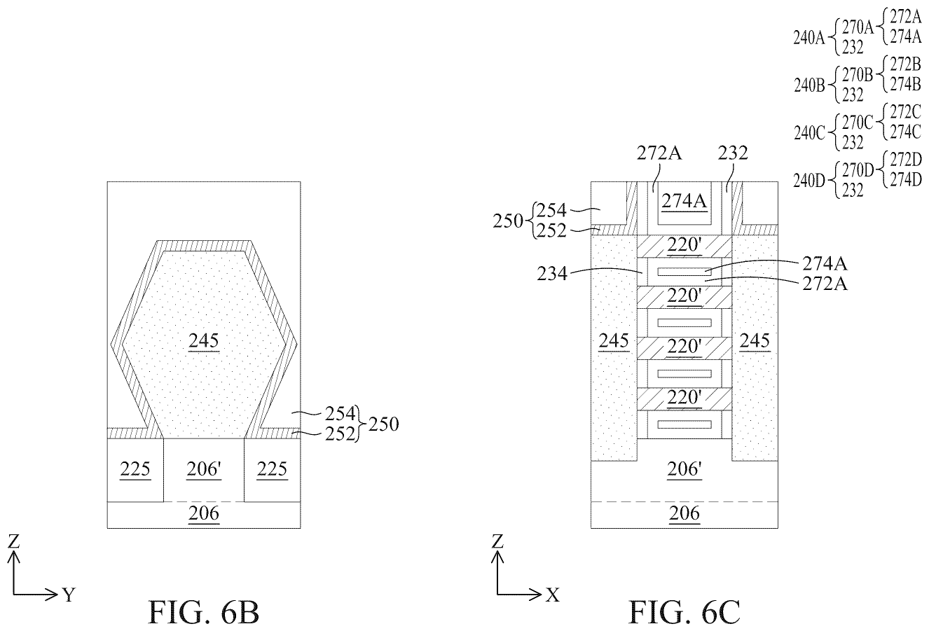

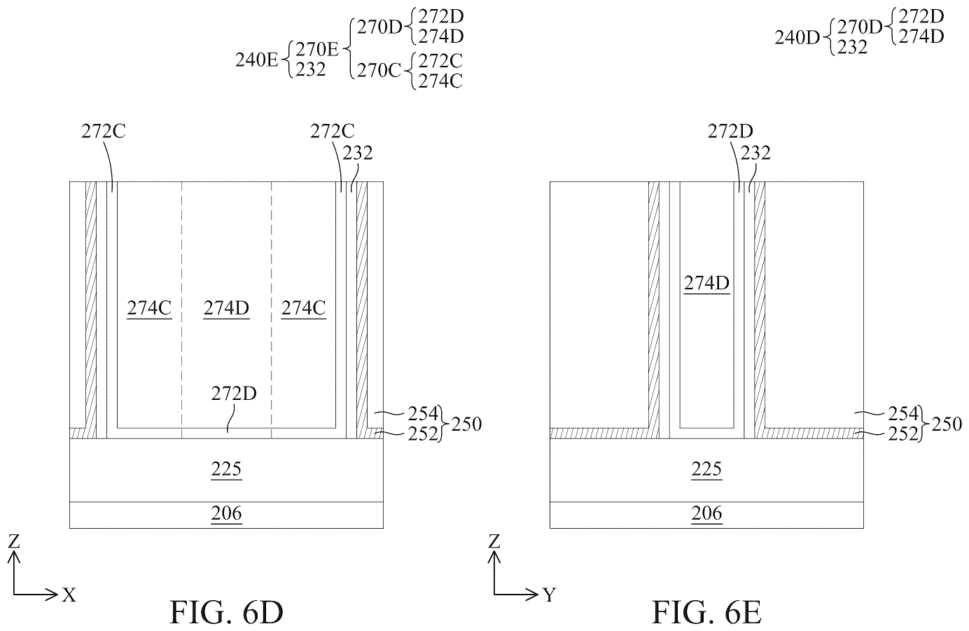

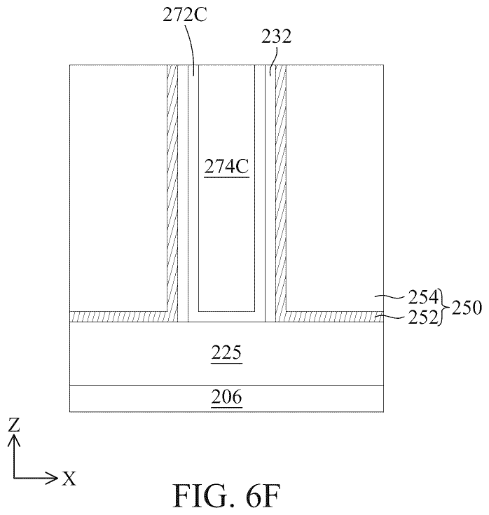

Turning to FIGS. 5A-5F and FIGS. 6A-6F, a gate replacement process is performed to replace dummy gates 230A-230D with metal gates and a channel release process is performed to form suspended channel layers in channel regions of fins 208A and fins 208B. Referring to FIGS. 5A-5F, gate openings 260A-260D are formed by removing dummy gates 230A-230D, respectively. Gate openings 260A expose channel regions of fins 208A, and gate openings 260B expose channel regions of fins 208B. Gate openings 260C and gate opening 260D expose substrate isolation structures 225, and gate opening 260D connects at least two gate openings 260C. For example, in FIG. 5D, gate openings 260C (formed by removing dummy gates 230C) and gate opening 260D (formed by removing dummy gate 230D) combine to form a gate opening 260E. A width of gate opening 260E (e.g., a sum of length l and (width W5×2)) is greater than a width of gate openings 260C (e.g., width W5). In some embodiments, gate openings 260A-260C are referred to as vertical gate openings (or trenches), and gate opening 260D and/or gate opening 260E are referred to as a horizontal gate opening (or trench), a gate bar opening, a gate support structure opening, or combinations thereof.

In some embodiments, an etching process selectively removes dummy gates 230A-230D with respect to semiconductor stacks 210, substrate isolation structures 225, gate spacers 232, ILD layer 254, CESL 252, or combinations thereof. In other words, the etching process removes dummy gates 230A-230D with no to negligible removal of semiconductor stacks 210, substrate isolation structures 225, gate spacers 232, ILD layer 254, CESL 252, or combinations thereof. For example, an etchant is selected that removes polysilicon (e.g., dummy gates 230A-230D and/or dummy gate electrodes thereof) at a higher rate than semiconductor materials (e.g., semiconductor layers 220, semiconductor layers 215, and mesas 206′) and dielectric materials (e.g., substrate isolation structures 225, gate spacers 232, ILD layer 254, CESL 252, etc.) (i.e., the etchant has a high etch selectivity with respect to polysilicon). The etching process is a dry etch, a wet etch, other suitable etch, or combinations thereof. In some embodiments, a patterned mask layer covers ILD layer 254, CESL 252, gate spacers 232, or combinations thereof, and the patterned mask layer has openings therein that expose dummy gates 230A-230D.

The channel release process may be performed after forming gate openings 260A-260D to provide suspended channel layers. For example, semiconductor layers 215 exposed by gate openings 260A and gate openings 260B may be selectively removed to form gaps between semiconductor layers 220 and gaps between semiconductor layers 220 and mesas 206′, thereby suspending semiconductor layers 220 over mesas 206′. Gate openings 260A and gate openings 260B are thus extended between semiconductor layers 220 and between semiconductor layers 220 and mesas 206′. In the depicted embodiment, four semiconductor layers 220 are vertically stacked along the z-direction and the four semiconductor layers 220 provide channels through which current may flow between respective source/drains 245. Semiconductor layers 220 may thus be referred to as channel layers 220′ (or suspended semiconductor layers 220′).

In some embodiments, an etching process selectively removes semiconductor layers 215 with no to negligible removal of mesas 206′, semiconductor layers 220, substrate isolation structures 225, gate spacers 232, inner spacers 234, dielectric layer 250, or combinations thereof. For example, an etchant is selected that etches/removes silicon germanium (i.e., semiconductor layers 215) at a higher rate than silicon (i.e., semiconductor layers 220 and mesas 206′) and dielectric materials (i.e., substrate isolation structures 225, gate spacers 232, inner spacers 234, CESL 252, ILD layer 254, or combinations thereof) (i.e., the etchant has a high etch selectivity with respect to silicon germanium). The etching process is a dry etch, a wet etch, other suitable etch, or combinations thereof. In some embodiments, before performing the etching process, an oxidation process converts semiconductor layers 215 into silicon germanium oxide features, and the etching process removes the silicon germanium oxide features. In some embodiments, a profile of channel layers 220′ may be modified to provide target dimensions and/or target shapes thereof. For example, an etching process may provide channel layers 220′ with cylindrical-shaped profiles (e.g., nanowires), rectangular-shaped profiles (e.g., nanobars), sheet-shaped profiles (e.g., nanosheets), or any other suitable shaped profile. In some embodiments, channel layers 220′ have nanometer-sized dimensions and may be referred to as “nanostructures,” alone or collectively. The present disclosure contemplates channel layers 220′ having any suitable dimensions, including sub-nanometer dimensions and/or super-nanometer dimensions.

Referring to FIGS. 6A-6F, gate stacks 270A-270D are formed in gate openings 260A-260D, respectively. Gate stacks 270A fill gate openings 260A, gaps between channel layers 220′ in gate openings 260A, and gaps between channel layers 220′ and mesas 206′ in gate openings 260A. Gate stacks 270B fill gate openings 260B, gaps between channel layers 220′ in gate openings 260B, and gaps between channel layers 220′ and mesas 206′ in gate openings 260B. Gate stacks 270C fill gate openings 260C, and gate stacks 270D fill gate openings 260D. Along a lengthwise direction of active regions (see, e.g., FIG. 6C), gate stacks 270A and gate stacks 270B are disposed between respective gate spacers 232, between respective inner spacers 234, between respective channel layers 220′, and between respective channel layers 220′ and respective mesas 206′. Along a widthwise direction of the active regions (e.g., in the Y-Z plane), gate stacks 270A and gate stacks 270B may surround and/or wrap respective channel layers 220′ (e.g., nanowires). Further, gate stacks 270C are disposed between respective gate spacers 232 and over respective substrate isolation structure 225 along the lengthwise direction of the active regions (see, e.g., FIG. 6F), and gate stacks 270D are disposed between respective gate spacers 232 and over respective substrate isolation structure 225 along the widthwise direction of the active regions (see, e.g., FIG. 6E). In gate support regions, gate stacks 270C and gate stack 270D may combine to form a gate stack 270E, which includes at least two gate stacks 270C and at least one gate stack 270D. Gate stack 270D and/or gate stack 270E may be referred to as a gate bar, a horizontal gate bar, a gate support structure, or combinations thereof.

After the gate replacement process, each gate structure 240A includes a respective gate stack 270A and gate spacers 232, each gate structure 240B includes a respective gate stack 270B and gate spacers 232, each gate structure 240C includes a respective gate stack 270C and gate spacers 232, gate structure 240D includes a respective gate stack 270D and gate spacers 232, and gate structure 240E includes gate stack 270E and gate spacers 232. Gate stacks 270A include a respective gate dielectric 272A and a respective gate electrode 274A, gate stacks 270B include a respective gate dielectric 272B and a respective gate electrode 274B, gate stacks 270C include a respective gate dielectric 272C and a respective gate electrode 274C, and gate stack 270D includes a gate dielectric 272D and a gate electrode 274D.

Gate dielectrics 272A-272D are disposed on channel layers 220′, mesas 206′, substrate isolation structures 225, or combinations thereof. Compositions and/or configurations of gate dielectrics 272A, gate dielectrics 272B, gate dielectrics 272C, gate dielectric 272D, or combinations thereof may be the same or different. Gate dielectric 272A-272D each include at least one dielectric gate layer, such as an interfacial layer and/or a high-k dielectric layer. The interfacial layer includes a dielectric material, such as SiO₂, SiGeOₓ, HfSiO, SiON, other dielectric material, or combinations thereof. The high-k dielectric layer includes a high-k dielectric material, which generally refers to dielectric materials having a dielectric constant that is greater than a dielectric constant of silicon dioxide (k≈3.9), such as HfO₂, HfSiO, HfSiO₄, HfSiON, HfLaO, HfTaO, HfTiO, HfZrO, HAlOₓ, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr)TiO₃ (BST), Si₃N₄, HfO₂—Al₂O₃, other high-k dielectric material, or combinations thereof. For example, gate dielectrics 272A-272D may each include a hafnium-based oxide (e.g., HfO₂) layer and/or a zirconium-based oxide (e.g., ZrO₂) layer. In some embodiments, the interfacial layer and/or the high-k dielectric layer has a multilayer structure.

Gate electrodes 274A-274D are disposed over gate dielectrics 272A-272D, respectively. Compositions and/or configurations of gate electrodes 274A, gate electrodes 274B, gate electrodes 274C, gate electrode 274D, or combinations thereof may be the same or different. Gate electrodes 274A-274D include at least one electrically conductive gate layer. The electrically conductive gate layer includes an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, gate electrodes 274A-274D include a work function layer. The work function layer is a conductive layer tuned to have a desired work function, such as an n-type work function or a p-type work function. The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, gate electrodes 274A-274D include a bulk layer over the gate dielectric and/or the work function layer. The bulk layer includes a suitable conductive material, such as Al, W, Cu, Ti, Ta, TiN, TaN, polysilicon, other suitable metal(s) and/or alloys thereof, or combinations thereof. In some embodiments, gate electrodes 274A-274D include a barrier (blocking) layer over the work function layer and/or the gate dielectric. The barrier layer includes a material that prevents or eliminates diffusion and/or reaction of constituents between adjacent layers and/or promotes adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Gate stacks 270A-270D are configured to achieve desired functionality according to design requirements of device 200. Gate stacks 270A-270D may thus have different layers in device region 202A, device region 202B, and isolation region 204 depending on configurations thereof, and gate stacks 270A-270D may have different layers within device region 202A, within device region 202B, and within isolation region 204 depending on configurations thereof. For example, a number, configuration, materials, or combinations thereof of layers of gate dielectrics 272A-272D and/or gate electrodes 274A-274D corresponding with first type transistor regions (e.g., n-type transistor regions) may be different than a number, configuration, materials, or combinations thereof of layers of gate dielectrics 272A-272D and/or gate electrodes 274A-274D corresponding with second type transistor regions (e.g., p-type transistor regions). In another example, a number, configuration, materials, or combinations thereof of layers of gate dielectrics 272A and/or gate electrodes 274A in device region 202A may be different than a number, configuration, materials, or combinations thereof of layers of gate dielectrics 272B and/or gate electrodes 274B in device region 202B. In yet another example, a number, configuration, materials, or combinations thereof of layers of gate dielectrics and/or gate electrodes in device regions (e.g., device region 202A and/or device region 202B) may be different than a number, configuration, materials, or combinations thereof of layers of gate dielectrics and/or gate electrodes in isolation regions (e.g., isolation region 204). Gate stacks 270A-270D may include numerous other layers, for example, capping layers, interface layers, diffusion layers, barrier layers, hard mask layers, or combinations thereof.

Forming gate stacks 270A-270D may include depositing gate dielectric material (e.g., interfacial layers and/or high-k dielectric layers) that partially fill gate openings 260A-260D, depositing gate electrode material (e.g., work function layers, barrier layers, bulk layers, etc.) that fill remainders of gate openings 260A-260D, and performing a planarization process to remove portions of the gate dielectric material and/or portions of the gate electrode material over dielectric layer 250. In some embodiments, fabrication of device 200 may further include etching back gate stacks 270A-270D and forming hard masks (e.g., self-aligned cap (SAC) structures) over the etched-back gate stacks 270A-270D. The hard masks include a material that is different than dielectric layer 250 and/or subsequently formed dielectric layers to achieve etch selectivity. In some embodiments, the hard masks include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, the hard masks include metal and oxygen and/or nitrogen, such as aluminum oxide (e.g., AlO or Al₂O₃), aluminum nitride (e.g., AlN), aluminum oxynitride (e.g., AlON), zirconium oxide, zirconium nitride, hafnium oxide (e.g., HfO or HfO₂), zirconium aluminum oxide (e.g., ZrAlO), other metal oxide, other metal nitride, or combinations thereof.

Referring to FIGS. 7A-7G, fabrication of device 200 may include forming a dielectric layer 280 over device 200 (e.g., over dielectric layer 250 and gate stacks 270A-270D) and forming source/drain contact isolation structures 285 over dielectric layer 280. Dielectric layer 280 may be configured and formed in a manner similar to dielectric layer 250. For example, dielectric layer 280 may include an ILD layer over a CESL. Source/drain contact isolation structures 285 extend lengthwise along the fin lengthwise direction (e.g., along the x-direction), such that source/drain contact isolation structures 285 have lengths in the x-direction, widths in the y-direction, and heights in the z-direction. Along the widthwise direction of the active regions (see, e.g., FIG. 7A), source/drain contact isolation structures 285 have a width W7, which may be less than spacings between fins 208A and/or spacings between fins 208B. Along the lengthwise direction of the active regions (see, e.g., FIG. 7A), source/drain contact isolation structures 285 span device region 202A, device region 202B, and isolation region 204.

In gate support regions of isolation region 204 (i.e., regions of isolation region 204 where gate structures 240D are inserted to improve structural integrity of gate structures 240C), source/drain contact isolation structures 285 are widened to prevent electrical shorting, which may result from unintended electrical connections and/or physical connections between gate stacks 270D and subsequently formed source/drain contacts. For example, middle source/drain contact isolation structure 285 of device 200 has a widened portion 285′ over gate structure 240D. Widened portion 285′ has a width W8 along the widthwise direction of the active regions that is greater than width W7. Width W8 is also greater than a width of gate stack 270D (e.g., width W6) to ensure that subsequently formed source/drain contacts are sufficiently spaced away from gate stack 270D. In the depicted embodiment (see, e.g., FIG. 7E), widened portion 285′ is disposed over and covers gate stack 270D, and widened portion 285′ extends laterally beyond both sidewalls of gate stack 270D. For example, widened portion 285′ may extend a distance d3 and a distance d4 beyond a first sidewall and a second sidewall, respectively, of gate stack 270D. Distance d3 may the same or different than distance d4. A length of widened portion 285′ (e.g., along the x-direction) may be configured so that widened portion 285′ is disposed over and covers gate structure 240E (i.e., gate structure 240D combined with portions of gate structures 240C connected thereto). In some embodiments, the length of widened portion 285′ is greater than or equal to a sum of a length of gate stack 270D and a sum of widths of at least two gate stacks 270C (e.g., length=length l+(2×width W5)). In some embodiments, the length of widened portion 285′ is greater than or equal to the length of gate stack 270D.

Source/drain contact isolation structures 285 include an electrically insulating material, such as a dielectric material. A composition of source/drain contact isolation structures 285 is different than a composition of dielectric layer 280 and/or a composition of dielectric layer 250 to enable selective etching/removal therebetween. For example, source/drain contact isolation structures 285 are formed of a dielectric material that is different than a dielectric material of dielectric layer 280 and/or a dielectric material of dielectric layer 250. In some embodiments, source/drain contact isolation structures 285 are formed of a dielectric material that includes silicon and oxygen, carbon, nitrogen, or combinations thereof. For example, source/drain contact isolation structures 285 may be formed of silicon oxide, silicon oxycarbide, silicon nitride, silicon oxycarbonitride, or combinations thereof. In some embodiments, source/drain contact isolation structures 285 are formed of a dielectric material that includes boron and oxygen, carbon, nitrogen, or combinations thereof. For example, source/drain contact isolation structures 285 may be formed of boron nitride. In some embodiments, source/drain contact isolation structures 285 are formed of a dielectric material that includes metal and oxygen, carbon, nitrogen, or combinations thereof. In some embodiments, source/drain contact isolation structures 285 are formed by depositing a source/drain contact isolation material over dielectric layer 280 and patterning the source/drain contact isolation material (e.g., by forming a patterned mask layer over the source/drain contact isolation material and etching/removing the source/drain contact isolation material exposed by openings in the patterned mask layer). The present disclosure contemplates a source/drain contact isolation layer (which collectively refers to source/drain contact isolation structures 285 collectively) having various patterns and/or width variations depending on a layout of the active regions (e.g., fins 208A, 208B), a layout of the active gates (e.g., gate structures 240A, 240B and/or gate stacks 270A, 270B), a layout of the dummy gates (e.g., gate structures 240C and/or gate stacks 270C), a layout of the gate support structures (e.g., gate structures 240D and/or gate stacks 270D), or combinations thereof. In some embodiments, dielectric layer 280 is omitted, and source/drain contact isolation structures 285 are formed directly on and physically contact dielectric layer 250 and/or gate stacks 270A-270D.

Referring to FIGS. 8A-8G, fabrication of device 200 may include forming source/drain contacts 290A-290C, which may be physically and/or electrically isolated from one another by source/drain contact isolation structures 285. Source/drain contacts 290A-290C extend along the gate lengthwise direction (e.g., along the y-direction), such that source/drain contacts 290A-290C have lengths in the y-direction, widths in the x-direction, and heights in the z-direction. Along the lengthwise direction of the active regions (see, e.g., FIG. 8A), source/drain contacts 290A have widths that are less than spacings between gate structures 240A, source/drain contacts 290B have widths that are less than spacings between gate structures 240B, and source/drain contacts 290C have widths that are less than spacings between gate structures 240C. Along the widthwise direction of the active regions (see, e.g., FIG. 8A), source/drain contacts 290A-290C have lengths that are less than or equal to spacings between source/drain contact isolation structures 285. In the depicted embodiment, each of source/drain contacts 290A-290C is between and physically contacts a first one of source/drain contact isolation structures 285 and a second one of source/drain contact isolation structures 285.

Source/drain contacts 290A may extend through a dielectric layer 292, dielectric layer 280, dielectric layer 250, or combinations thereof to respective source/drains 245 in device region 202A (see, e.g., FIG. 8B and FIG. 8C). Source/drain contacts 290B may extend through dielectric layer 292, dielectric layer 280, dielectric layer 250, or combinations thereof to respective source/drains 245 in device region 202B. Source/drain contacts 290C may extend through dielectric layer 292, dielectric layer 280, dielectric layer 250, or combinations thereof to substrate isolation structures 225 in isolation region 204 (see, e.g., FIG. 8E, FIG. 8F, and FIG. 8G). In the depicted embodiment, source/drain contacts 290C extend into substrate isolation structures 225, such that source/drain contacts 290C extend below bottoms of gate stacks 270C and/or gate stacks 270D. In some embodiments, source/drain contacts 290C may stop at and not extend into substrate isolation structures 225. Because source/drain contact isolation structures 285 have widened portion(s) 285′ in gate support regions of isolation region 204, source/drain contacts 290C are separated by a first distance (e.g., width W8) in the gate support regions (see, e.g., FIG. 8E) and a second distance (e.g., width W7) in gate support-free regions (see, e.g., FIG. 8G). Enlarging spacing between source/drain contacts 290C in the gate support regions ensures that sufficient spacing is between source/drain contacts 290C and gate stack 270D (e.g., distance d3 and/or distance d4), thereby reducing the risk of source/drain contacts 290C electrically and/or physical connecting to gate stack 270D and causing short circuits. In some embodiments, a distance d5 between gate stacks 270C and source/drain contacts 290C (i.e., in the gate support-free regions of isolation region 204) is less than distance d3 and/or distance d4 between gate stack 270D and source/drain contacts 290C (i.e., in the gate support regions).

Source/drain contacts 290A-290C include tungsten, ruthenium, cobalt, copper, aluminum, iridium, palladium, platinum, nickel, low resistivity metal constituent, alloys thereof, or combinations thereof. In the depicted embodiment, source/drain contacts 290A-290C include tungsten, ruthenium, cobalt, alloys thereof, or combinations thereof. For example, source/drain contacts 290A-290C may be tungsten contacts, ruthenium contacts, or cobalt contacts. Source/drain contacts 290A-290C may have the same or different configurations and/or compositions. Source/drain contacts 290A-290C may be formed by forming dielectric layer 292 over source/drain contact isolation structures 285 and dielectric layer 280; forming source/drain contact openings that extend through dielectric layer 292, dielectric layer 280, dielectric layer 250, or combinations thereof to expose source/drains 245 or substrate isolation structures 225; depositing at least one electrically conductive material over the dielectric layer 292 that fills the source/drain contact openings; and performing a planarization process to remove any of the electrically conductive material that is disposed over a top of source/drain contact isolation structures 285 and/or dielectric layer 292. The planarization process may be performed until reaching and exposing source/drain contact isolation structures 285 and/or dielectric layer 292. Remainders of the electrically conductive material form metal plugs and, in some embodiments, metal liners of source/drain contacts 290A-290C. In some embodiments, a silicidation process is performed to form silicide layers over source/drains 245 before depositing the at least one electrically conductive material in the source/drain contact openings.

In some embodiments, forming the source/drain contact openings includes forming a patterned mask layer over dielectric layer 292 that has openings therein that overlap source/drains 245 in device region 202A, source/drains 245 in device region 202B, and substrate isolation structures 225 in isolation region 204 and selectively etching dielectric material (e.g., dielectric layer 292, dielectric layer 280, dielectric layer 250, or combinations thereof) exposed by the openings of the patterned mask layer with no to negligible etching of semiconductor materials (e.g., source/drains 245). In the depicted embodiment, since substrate isolation structures 225 are formed of a dielectric material, the etching may remove portions thereof, such that the source/drain contact openings in isolation region 204 extend into substrate isolation structures 225. In some embodiments, the etching is configured to stop upon reaching and/or exposing source/drains 245. The etching is a dry etch, a wet etch, other suitable etch, or combinations thereof. One or more deposition processes may be performed to form the electrically conductive material that fills the source/drain contact openings.

In FIGS. 8A-8G, device 200 includes transistors in device region 202A and transistors in device region 202B. For example, in device region 202A, a transistor may include respective channel layers 220′, respective source/drains 245, and a respective gate structure 240A (e.g., a respective gate stack 270A and respective gate spacers 232). The respective gate structure 240A is disposed between the respective source/drains 245 along the x-direction, and inner spacers 234 are disposed between the respective gate structure 240A and the respective source/drains 245. Further, the respective gate stack 270A engages the respective channel layers 220′, and the respective channel layers 220′ extend between the respective source/drains 245 along the x-direction. The respective gate structure 240A is disposed on at least two sides of the respective channel layers 220′. For example, the respective gate structure 240A has a respective gate dielectric 272A and a respective gate electrode 274A that may surround the respective channel layers 220′ (e.g., in a Y-Z cross-sectional view). In device region 202B, a transistor may include respective channel layers 220′, respective source/drains 245, and a respective gate structure 240B (e.g., a respective gate stack 270B and respective gate spacers 232). The respective gate structure 240B is disposed between the respective source/drains 245 along the x-direction, and inner spacers 234 are disposed between the respective gate structure 240B and the respective source/drains 245. Further, the respective gate stack 270B engages the respective channel layers 220′, and the respective channel layers 220′ extend between the respective source/drains 245 along the x-direction. The respective gate structure 240B is disposed on at least two sides of the respective channel layers 220′. For example, the respective gate structure 240B has a respective gate dielectric 272B and a respective gate electrode 274B that may surround the respective channel layers 220′ (e.g., in a Y-Z cross-sectional view).

Applying voltage to gate stacks 270A and/or gate stacks 270B may enable current to flow through respective channel layers 220′ between the respective source/drains 245. Gate structures 240A, 240B that form portions of transistors may thus be referred to as active gate structures, and gate stacks 270A, 270B that form portions of transistors may be referred to as active gate stacks and/or active gates. “Active gate structure,” “active gate stack,” and “active gate” generally refers to an electrically functional gate structure (and/or gate stack), whereas “dummy gate structure” generally refers to an electrically non-functional gate structure (and/or gate stack). A dummy gate structure may mimic physical properties of an active gate structure, such as physical dimensions and/or layers of the active gate structure, yet is electrically inoperable (i.e., applying voltage to the dummy gate structure does not enable current to flow through channels and/or between source/drains). In the depicted embodiment, device 200 includes dummy gate structures in isolation region 204, such as gate structures 240C and/or gate stacks 270C thereof. Further, because source/drain contacts 290C are connected to substrate isolation structures 225, not electrically conductive features, source/drain contacts 290C may be referred to as dummy source/drain contacts. Gate structures 240C, gate stacks 270C thereof, source/drain contacts 290C, or combinations thereof may enable a substantially uniform processing environment (e.g., by reducing (or preventing) CMP-induced dishing effects).

Device 200 further includes gate support structures, such as gate structures 240D and/or gate stacks 270D thereof, which may also be referred to as gate support bars and/or dummy gate support bars (since gate structures 240D and/or gate stacks 270D thereof are dummy gate structures). Gate support structures may improve reliability and/or structural integrity of device 200 in isolation region 204. Referring to FIG. 13A and FIG. 13B, gate structures 240A (and/or gate stacks 270A thereof) and gate structures 240B (and/or gate stacks 270B thereof) are formed over both active regions (e.g., channel regions of fins 208A and fins 208B, respectively, which may include respective channel layers 220′) and substrate isolation structure 225. Since gate structures 240A and gate structures 240B may adhere well to the active regions, gate structures 240A and gate structures 240B are anchored and structurally supported by the active regions, which prevents collapsing and/or bending of gate structures 240A and gate structures 240B even as gate heights may increase with scaled IC technology nodes. Such anchoring also provides gate structures 240A and gate structures 240B with varying heights (e.g., height h1 and height h2) along their lengths, which further reduces collapsing and/or bending. In contrast, gate structures 240C are formed over substrate isolation structures 225. Since gate structures 240C may not adhere as well to substrate isolation structures 225 (e.g., dielectric material vs. semiconductor material) and gate structures 240C have greater overall heights (i.e., gate structures 240C have height h1 along their lengths because gate structures 240C are not also disposed over active regions), gate structures 240C may undesirably peel from substrate isolation structures 225, bend, collapse, or combinations thereof, such as depicted in FIG. 13A. Such degrades device performance, device reliability, device yield, or combinations thereof. This issue may be exacerbated by (unintentional or intentional) etching of substrate isolation structure 225 that results in gate structures 240C being supported by isolation mesas 225′, which are narrower than substrate isolation structure 225 and provide even less structural stability to gate structures 240C. By inserting gate support structures (e.g., gate structures 240D and/or gate stacks 270D thereof) into isolation region 204, gate structures 240C are provided with additional support and/or anchoring, which may reduce and/or prevent collapsing and/or bending thereof, such as depicted in FIG. 13B. Gate support structures may easily be integrated into existing device fabrication processes. Different embodiments may have different advantages, and no particular advantage is necessarily required of any embodiment.

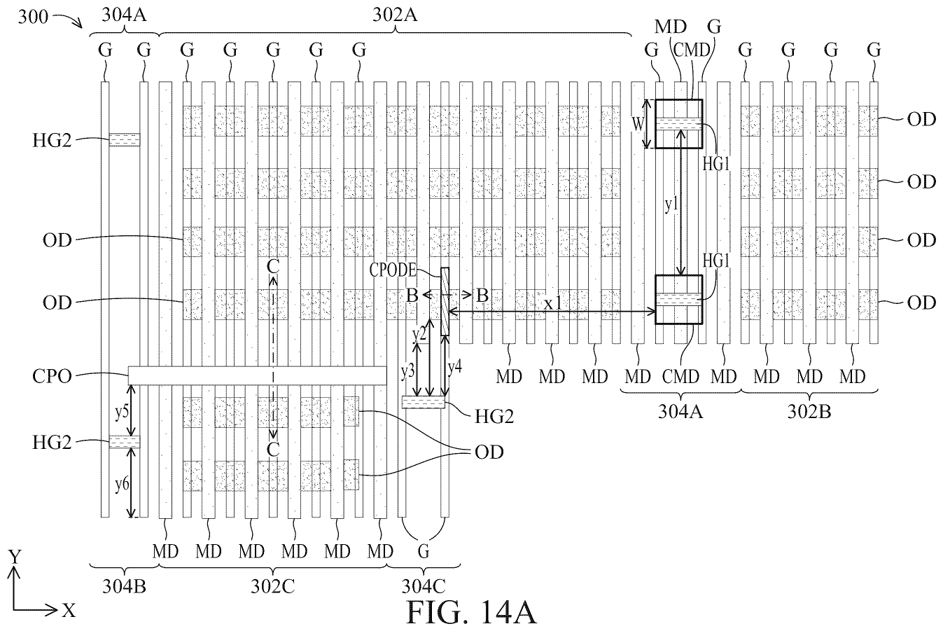

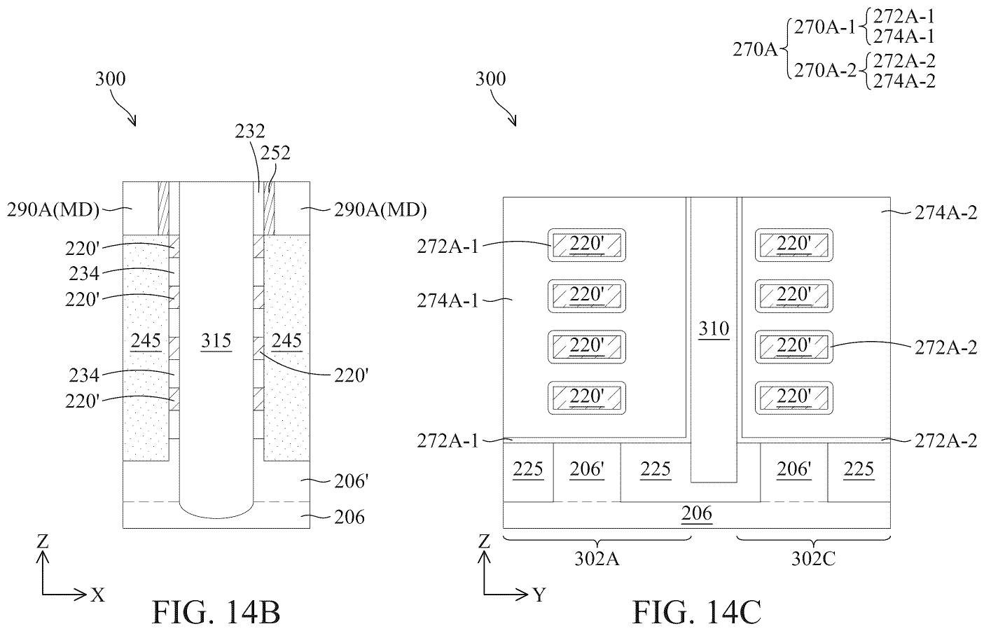

Gate support structures, such as described herein, may integrated into devices and/or device layouts according to a set of design rules. Referring to FIGS. 14A-14C, a device 300 having gate support structures is configured and arranged according to a set of design rules, as described further below. FIG. 14A is a top view of device 300, in portion or entirety, according to various aspects of the present disclosure. FIG. 14B is a cross-sectional view of device 300, in portion or entirety, along line B-B of FIG. 14A, according to various aspects of the present disclosure. FIG. 14C is a cross-sectional view of device 300, in portion or entirety, along line C-C of FIG. 14A, according to various aspects of the present disclosure. Device 300 is similar in many respects to device 200. Similar features of device 300 and device structure 200 are thus identified by the same reference numerals for clarity and simplicity. FIGS. 14A-14C are discussed concurrently herein for ease of description and understanding. FIGS. 14A-14C have been simplified for the sake of clarity to better understand the inventive concepts of the present disclosure. Additional features may be added in device 300, and some of the features described below may be replaced, modified, or eliminated in other embodiments of device 300.

Device 300 includes areas that include active regions (e.g., a device region 302A, a device region 302B, and a device region 302C) and areas that do not include active regions (i.e., non-active region areas, such as an isolation region 304A, an isolation region 304B, and an isolation region 304C). Device regions 302A-302C each include respective active regions (OD), gates (G), and source/drain contacts (MD). Active regions extend lengthwise along a first direction (e.g., x-direction), gates extend lengthwise along a second direction (e.g., y-direction) different than the first direction, and source/drain contacts extend lengthwise along the second direction. Active regions may include channel structures (e.g., a stack of channel layers 220′) disposed between source/drains (e.g., source/drains 245), and gates may be disposed over and engage the channel structures (e.g., gates may wrap and/or surround channel layers 220′). Gates and active regions may combine to form transistors in device regions 302A-302C.

Device 300 may include one or more gate isolation structures (CPO or CMG). In the depicted embodiment, a gate isolation structure physically and/or electrically isolates gates of different device regions, such as gates of device region 302A from gates of device region 302C. The gate isolation structure extends lengthwise along the first direction (i.e., the lengthwise direction of the active regions). In some embodiments, gates of device region 302A and gates of device region 302C may be formed from a gate line that is cut into two gates, for example, by replacing a portion of the gate line with an electrically insulating material, such as a dielectric material. In FIG. 14C, the gate isolation structure may include a dielectric material 310 that is disposed between a gate of device region 302A (e.g., a gate stack 270A-1 having a gate dielectric 272A-1 and a gate electrode 274A-1) and a gate of device region 302C (e.g., a gate stack 270A-2 having a gate dielectric 272A-2 and a gate electrode 274A-2), which may be formed by replacing a portion of a respective gate (e.g., a respective gate stack 270A) with dielectric material 310. The gate isolation structure may extend into substrate isolation structures 225, such that the gate isolation structure extends below bottoms of the gates (e.g., beyond gate stack 270A-1 and gate stack 270A-2). Dielectric material 310 may be a single layer or multiple layers.

Device 300 may also include one or more active region isolation structures (CPODE), which may replace portions of gates. In the depicted embodiment, an active region isolation structure physically and/or electrically isolates active regions of different devices, such as a first active region of a first device in device region 302A from a second active region of a second device in device region 302A. The active region isolation structure extends lengthwise along the second direction (i.e., the lengthwise direction of the gates). In such embodiments, active regions of devices within a device region, such as device region 302A, may be formed from an active region line that is cut into two active regions, for example, by replacing a portion of the active region line and/or a gate line traversing the active region line with an electrically insulating material, such as a dielectric material. In FIG. 14B, the active region isolation structure may include a dielectric material 315 that is disposed between a first active region of a first device (e.g., a respective source/drain 245 thereof) and a second active region of a second device (e.g., a respective source/drain 245 thereof). The active region isolation structure (e.g., dielectric material 315) may extend into substrate isolation structures 225, such that the active region isolation structure extends below bottoms of source/drains 245 and/or channel layers 220′. Dielectric material 315 may be a single layer or multiple layers.

Isolation region 304A is disposed between device region 302A and device region 302B, isolation region 304B is disposed adjacent to device region 302A and device region 302C, and isolation region 304C is disposed adjacent to device region 302C, such that device region 302A is disposed between isolation region 304A and isolation region 304B and device region 302C is disposed between isolation region 304B and isolation region 304C. Isolation region 304A includes respective gates, respective source/drain contacts, source/drain contact isolation structures (CMD), and respective gate support structures (HG1). Isolation region 304B includes respective gates and respective gate support structures (HG2), but not source/drain contacts and/or source/drain contact isolation structures. The gate support structures extend lengthwise along the first direction (i.e., the lengthwise direction of the active regions).

Dimensions and/or spacings corresponding with the gate support structures may be configured differently depending on whether the gate support structures are formed in regions with or without source/drain contacts. For example, dimensions and/or spacings corresponding with gate support structures (e.g., HG2) in isolation region 304B and isolation region 304C, which are free of source/drain contacts, may be relaxed relative to dimensions and/or spacings corresponding with gate support structures (e.g., HG1) in isolation region 304A, which includes source/drain contacts. In some embodiments, lengths of gate support structures in isolation region 304B and/or isolation region 304C may be configured greater than lengths of gate support structures in isolation region 304A. For example, gate support structures in isolation region 304A may be connected to two gates, while gate support structures in isolation region 304B and/or isolation region 304C may be connected to two to six gates. In such example, a length of a gate support structure in isolation region 304B and/or isolation region 304C (e.g., along the x-direction) may be about five times greater than a length of a gate support structure in isolation region 304A (e.g., along the x-direction). In some embodiments, gate support structures in isolation regions 304A-304C have widths (e.g., along the y-direction) that are about 8 nm to about 12 nm (e.g., 10 nm), lengths of gate support structures in isolation region 304A are less than or equal to about 54 nm, and lengths of gate support structures in isolation region 304B and/or isolation region 304C are less than or equal to about 270 nm.

In some embodiments, within a region that includes gate support structures, a spacing y1 between gate support structures along the y-direction (e.g., along the gate lengthwise direction) is greater than a spacing between gate support structures along the x-direction (e.g., along the active region lengthwise direction). For example, spacing y1 is about 4 to about 5 times greater than spacing between gate support structures along the x-direction. In some embodiments, spacing y1 is greater than or equal to about 224 nm and spacing between gate support structures along the x-direction is greater than about 48 nm.

In some embodiments, a spacing y2 between gate support structures and active regions (e.g., sidewalls thereof) along the y-direction is configured to reduce the risk of short circuits forming between the gate support structures and the active regions. For example, spacing y2 may be greater than or equal to about 130 nm. In some embodiments, a spacing y3 between gate support structures and ends of source/drain contacts along the y-direction is configured to reduce the risk of short circuits forming between the gate support structures and the source/drain contacts. For example, spacing y3 may be greater than or equal to about 100 nm. In some embodiments, widths W of source/drain contact isolation structures (e.g., along the y-direction) are configured about six to about nine times greater than widths of gate support structures in isolation region 304A to reduce the risk of short circuits forming between the gate support structures and the source/drain contacts. For example, gate support structures in isolation region 304A may have widths (e.g., along the y-direction) that are about 8 nm to about 12 nm (e.g., 10 nm), and widths W may be about 68 nm to about 72 nm.

In some embodiments, a spacing y4 between gate support structures and ends of active region isolation structures along the y-direction is configured to reduce the risk of short circuits forming between the gate support structures and the active regions. For example, spacing y4 may be greater than or equal to about 135 nm. In some embodiments, a spacing x1 between gate support structures and active region isolation structures (e.g., sidewalls thereof) along the x-direction is configured to reduce the risk of short circuits forming between the gate support structures and the active regions. For example, spacing x1 may be greater than or equal to about 94.5 nm. In some embodiments, spacing y4 is about 1.25 to about 1.5 times greater than spacing x1. In some embodiments, a spacing y5 between gate support structures and gate isolation structures (e.g., sidewalls thereof) along the y-direction is configured to reduce the risk of short circuits forming between the gate support structures and the active regions. For example, spacing y5 may be greater than or equal to about 48 nm. In some embodiments, a spacing y6 between gate support structures and ends of gates along the y-direction is configured to optimize locations of gate support structures and thus optimize structural integrity of gates. For example, spacing y5 may be greater than or equal to about 100 nm.

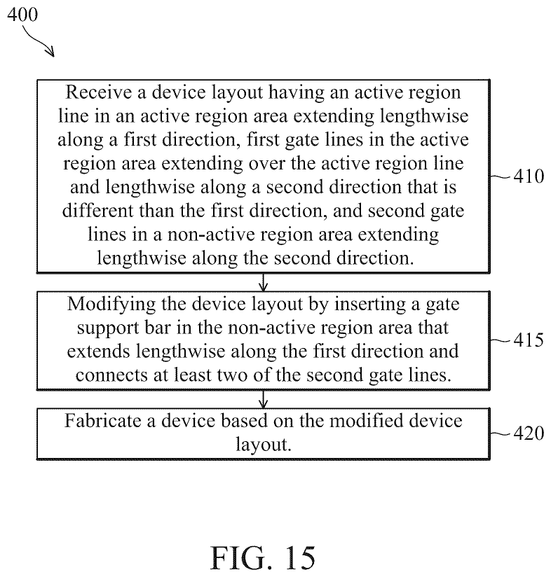

FIG. 15 is a flow chart of a method 400, in portion or entirety, for improving device reliability and structural integrity of a device, according to various aspects of the present disclosure. At block 410, method 400 includes receiving a device layout having an active region line in an active region area extending lengthwise along a first direction, first gate lines in the active region area extending over the active region line and lengthwise along a second direction that is different than the first direction, and second gate lines in a non-active region area extending lengthwise along the second direction. The first gate lines may be active gate lines and represent active gates, and the second gate lines may be dummy gate lines and represent dummy gates. The active region line may represent channel regions and/or source/drain regions. At block 415, method 400 includes modifying the device layout by inserting a gate support bar in the non-active region area that extends lengthwise along the first direction and connects at least two of the second gate lines. The gate support bar may be a dummy gate line and/or represent a dummy gate. At block 420, method 400 includes fabricating a device based on the modified device layout. Additional processing is contemplated by the present disclosure. Additional steps may be provided before, during, and after method 400, and some of the steps described may be moved, replaced, or eliminated for additional embodiments of method 400.

The present disclosure provides for many different embodiments. An exemplary method includes forming an active region in a device region. The active region extends lengthwise along a first direction and widthwise along a second direction. The method further includes forming an isolation structure in the device region and an isolation region. The isolation structure in the device region is adjacent to the active region. In some embodiments, the active region includes a lower portion and an upper portion, where the isolation structure is adjacent to the lower portion of the active region and the upper portion of the active region is disposed above and/or extends from the isolation structure. The method further includes forming first gates over the active region and the isolation structure in the device region, second gates over the isolation structure in the isolation region, and a third gate over the isolation structure in the isolation region. The first gates and the second gates extend lengthwise along the second direction, the third gate extends lengthwise along the first direction, and the third gate is connected to at least two of the second gates. In some embodiments, the first gates, the second gates, and the third gate are formed at the same time. In some embodiments, the first gates have a first spacing therebetween, the second gates have the first spacing therebetween, the first gates have a first height over the active region, and the second gates have a second height over the isolation structure. The second height is greater than the first height.

In some embodiments, the method further includes forming a contact isolation structure over the first gates, the second gates, and the third gate. The contact isolation structure extends lengthwise along the first direction. The contact isolation structure has a first width along the second direction over the first gates and a second width along the second direction over the third gate. The first width is less than the second width. In some embodiments, the contact isolation structure has the second width over the second gates. In some embodiments, the contact isolation structure is a first contact isolation structure, and the method further includes forming a second contact isolation structure over the first gates and the second gates. The second contact isolation structure extends lengthwise along the first direction, and the second contact isolation structure has the first width along the second direction over the first gates. The second contact isolation structure may further have the first width over the second gates.

In some embodiments, the method further includes forming a first source/drain contact in the device region and a second source/drain contact in the isolation region. The first source/drain contact and the second source/drain contact extend lengthwise along the second direction. The first source/drain contact is disposed on the active region and the second source/drain contact is disposed on the isolation structure. The first source/drain contact is disposed between a first one of the first gates and a second one of the first gates, and the second source/drain contact is disposed between a first one of the second gates and a second one of the second gates. In some embodiments, a first spacing is between the second source/drain contact and the first one of the second gates along the first direction, and a second spacing is between the second source/drain contact and the third gate along the second direction. The second spacing is greater than the first spacing.

In some embodiments, forming the first gates over the active region and the isolation structure in the device region, the second gates over the isolation structure in the isolation region, and the third gate over the isolation structure in the isolation region includes forming first dummy gate stacks that extend lengthwise along the second direction over the active region and the isolation structure in the device region, second dummy gate stacks that extend lengthwise along the second direction over the isolation structure in the isolation region, and a third dummy gate stack that extends lengthwise along the second direction over the isolation structure in the isolation region. The third dummy gate stack is connected to at least two of the second dummy gate stacks. The method may further include removing the first dummy gate stacks, the second dummy gate stacks, and the third dummy gate stack to form first gate openings, second gate openings, and a third gate opening, respectively. The first gate openings expose the active region, the second gate openings expose the isolation structure, and the third gate opening exposes the isolation structure. The third gate opening is connected to at least two of the second gate openings. The method may further include forming first gate stacks over the active region in the first gate openings, second gate stacks over the isolation structure in the second gate openings, and a third gate stack over the isolation structure in the third gate opening. In some embodiments, the method further includes, before removing the first dummy gate stacks, the second dummy gate stacks, and the third dummy gate stack, forming source/drain recesses in source/drain regions of the active region and forming source/drains in the source/drain recesses. The first gate openings may expose channel regions of the active region.

An exemplary device structure includes first gates extending lengthwise along a first direction in a device region, second gates extending lengthwise along the first direction in an isolation region, and a gate support bar extending lengthwise along a second direction in the isolation region. The second direction is different than the first direction. The first gates are disposed over an isolation structure and an active region, the second gates are disposed over the isolation structure, and the gate support bar is disposed over the isolation structure. The first gates have a first height over the isolation structure, the first gates have a second height over the active region, and the first height is greater than the second height. The second gates have a third height over the isolation structure, and the third height is greater than the second height. The gate support bar is connected to at least two of the second gates.

In some embodiments, the gate support bar has the third height over the isolation structure. In some embodiments, the device region is free of gate support bars extending lengthwise along the second direction. In some embodiments, the isolation region is free of active regions. In some embodiments, the active region includes a channel structure disposed between a first source/drain and a second source/drain, and at least one of the first gates is disposed over the channel structure and between the first source/drain and the second source/drain. The channel structure extends lengthwise along the second direction.

In some embodiments, the device structure further includes a source/drain contact isolation structure that extends lengthwise along the second direction. The source/drain contact isolation structure is disposed over the first gates, the second gates, and the gate support bar. The source/drain contact isolation structure has a first width along the first direction over the gate support bar and a second width along the first direction over the first gates. The first width is greater than the second width.

In some embodiments, the device region is a first device region, the active region is a first active region, and the device structure further includes fourth gates extending lengthwise along the first direction in a second device region. The fourth gates are disposed over the isolation structure and a second active region, the fourth gates have a fourth height over the isolation structure, the fourth gates have a fifth height over the second active region, and the fourth height is greater than the fifth height. The isolation region may be disposed between the first device region and the second device region along the second direction, and the third height is greater than the fifth height.

In some embodiments, the device structure further includes a source/drain contact isolation structure that extends lengthwise along the second direction. The source/drain contact isolation structure is disposed over the first gates, the second gates, and the gate support bar. The source/drain contact isolation structure has a first width along the first direction over the gate support bar and a second width along the first direction over the first gates. The first width is greater than the second width. In some embodiments, the source/drain contact isolation structure has the second width along the first direction over the second gates.

In some embodiments, the device structure further includes first source/drain contacts disposed in the device region and second source/drain contacts disposed in isolation region. At least one of the first source/drain contacts is disposed on and connected to the active region, and at least one of the second source/drain contacts is disposed on and extends into the isolation structure. In some embodiments, a first spacing between the gate support bar and the second source/drain contacts along the first direction is greater than a second spacing between the second gates and the second source/drain contacts along the second direction.

In some embodiments, the gate support bar is disposed in a gate support region of the isolation region, and the gate support bar includes first gate spacers disposed along first sidewalls of a first gate stack. The first gate stack includes a first gate dielectric and a first gate electrode. The gate support bar may be connected to a first one of the second gates and a second one of the second gates. The first one of the second gates includes second gate spacers disposed along second sidewalls of a second gate stack, and the second gate stack includes a second gate dielectric and a second gate electrode. The second one of the second gates includes a third gate stack having third gate spacers disposed along third sidewalls of the third gate stack, and the third gate stack includes a third gate dielectric and a third gate electrode. In the gate support region along the first direction, the first gate dielectric may wraps the first gate electrode and the first gate dielectric may form the first sidewalls of the first gate stack. In the gate support region along the second direction, the first gate electrode may be disposed between the second gate electrode and the third gate electrode, the second gate dielectric may be disposed between the second gate electrode and one of the second gate spacers, and the third gate dielectric may be disposed between the third gate electrode and one of the third gate spacers.

An exemplary device layout includes a first active gate line, a second active gate line, a first dummy gate line, and a second dummy gate line oriented lengthwise along a first direction. The device layout further includes a dummy gate support bar oriented lengthwise along a second direction that is different than the first direction. The dummy gate support bar extends along the second direction from the first dummy gate line to the second dummy gate line. The device layout further includes an active region oriented lengthwise along the second direction. The first active gate line and the second active gate line are disposed over the active region. In some embodiments, the active region includes a first active region and a second active region, the first active gate line is disposed over the first active region, the second active gate line is disposed over the second active region, and the first dummy gate line and the second dummy gate line are disposed between first active gate line and the second active gate line.

In some embodiments, the device layout further includes a first source/drain contact isolation line and a second source/drain contact isolation line oriented lengthwise along the second direction. The first source/drain contact isolation line is disposed over the first active gate line, the second active gate line, the first dummy gate line, and the second dummy gate line. The second source/drain contact isolation line is disposed over the first active gate line, the second active gate line, the first dummy gate line, the second dummy gate line, and the dummy gate support bar. The first source/drain contact isolation line has a first width along the second direction over the first active gate line, the second active gate line, the first dummy gate line, and the second dummy gate line. The second source/drain contact isolation line has the first width over the first active gate line and the second active gate line and a second width along the second direction over the dummy gate support bar. The second width is greater than the first width. In some embodiments, the second source/drain contact isolation line has the second width over the first dummy gate line and the second dummy gate line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming first active regions and second active regions extending lengthwise along a first direction, wherein the first active regions are formed in a first device region, the second active regions are formed in a second device region, and an isolation region extends along the first direction from the first device region to the second device region; and
forming first gate structures over the first active regions in the first device region, second gate structures over the second active regions in the second device region, and a third gate structure over an isolation structure in the isolation region, wherein:
the first gate structures, the second gate structures, and the third gate structure extend lengthwise along a second direction, wherein the second direction is different from the first direction,
in a top view, the first gate structures and the second gate structures have line-shaped profiles, and
in the top view, the third gate structure has an H-shaped profile.

2. The method of claim 1, wherein:
the forming the first active regions and the forming the second active regions includes aligning the first active regions and the second active regions along the first direction; and
the forming the third gate structure includes aligning a first direction extending segment of the third gate structure with a respective one of the first active regions and a respective one of the second active regions.

3. The method of claim 2, wherein the aligning includes center-aligning.

4. The method of claim 2, wherein the aligning includes top-aligning.

5. The method of claim 2, wherein the aligning includes bottom-aligning.

6. The method of claim 1, further comprising forming contact isolation structures that extend lengthwise along the first direction over the first device region, the isolation region, and the second device region, wherein:
first ones of the contact isolation structures extend over second direction extending segments of the third gate structure, wherein the first ones of the contact isolation structures have line-shaped profiles in the top view; and
a second one of the contact isolation structures extends over a first direction extending segment of the third gate structure, wherein the second one of the contact isolation structures has a line-shaped profile in the first device region, a line-shaped profile in the second device region, and a square-shaped profile in the isolation region over the first direction extending segment of the third gate structure in the top view.

7. The method of claim 1, further comprising forming first source/drain contacts over the first active regions, second source/drain contacts over the second active regions, and third source/drain contacts over the isolation region, wherein:
the first source/drain contacts, the second source/drain contacts, and the third source/drain contacts extend lengthwise along the second direction;
the first source/drain contacts are disposed between respective first gate structures along the first direction, the second source/drain contacts are disposed between respective second gate structures along the first direction, and the third source/drain contacts are disposed between second direction extending segments of the third gate structure along the first direction; and
a first direction extending segment of the third gate structure is not overlapped by the third source/drain contacts in the top view.

8. The method of claim 7, further comprising forming the first source/drain contacts, the second source/drain contacts, and the third source/drain contacts at the same time.

9. The method of claim 1, further comprising forming the first gate structures, the second gate structures, and the third gate structure at the same time.

10. A device structure comprising:
a first device region, a second device region, and an isolation region that extends along a first direction from the first device region to the second device region;
first active regions disposed in the first device region and second active regions disposed in the second device region, wherein the first active regions extend lengthwise along the first direction and the second active regions extend lengthwise along the first direction;
an isolation structure disposed in the first device region, the second device region, and the isolation region, wherein the isolation structure is disposed around the first active regions and the isolation structure is disposed around the second active regions; and
first gate structures disposed over the first active regions in the first device region, second gate structures disposed over the second active regions in the second device region, and a third gate structure disposed over the isolation structure in the isolation region, wherein:
the first gate structures, the second gate structures, and the third gate structure extend lengthwise along a second direction, wherein the second direction is different from the first direction,
in a top view, the first gate structures have line-shaped profiles and the second gate structures have line-shaped profiles, and
in the top view, the third gate structure has an H-shaped profile.

11. The device structure of claim 10, wherein the first device region is an n-type multigate device region, and the second device region is a p-type multigate device region.

12. The device structure of claim 10, wherein the first active regions and the second active regions are center-aligned along the first direction and a first direction extending segment of the third gate structure is aligned with a respective one of the first active regions and a respective one of the second active regions.

13. The device structure of claim 10, wherein the first active regions and the second active regions are top-aligned along the first direction and a first direction extending segment of the third gate structure is aligned with a respective one of the first active regions and a respective one of the second active regions.

14. The device structure of claim 10, wherein the first active regions and the second active regions are bottom-aligned along the first direction and a first direction extending segment of the third gate structure is aligned with a respective one of the first active regions and a respective one of the second active regions.

15. The device structure of claim 10, further comprising contact isolation structures that extend lengthwise along the first direction over the first device region, the isolation region, and the second device region, wherein:
first ones of the contact isolation structures extend over second direction extending segments of the third gate structure, wherein the first ones of the contact isolation structures have line-shaped profiles in the top view; and
a second one of the contact isolation structures extends over a first direction extending segment of the third gate structure, wherein the second one of the contact isolation structures has a line-shaped profile in the first device region, a line-shaped profile in the second device region, and a square-shaped profile in the isolation region over a first direction extending segment of the third gate structure in the top view.

16. The device structure of claim 10, further comprising first source/drain contacts over the first active regions, second source/drain contacts over the second active regions, and third source/drain contacts over the isolation region, wherein:
the first source/drain contacts, the second source/drain contacts, and the third source/drain contacts extend lengthwise along the second direction;
the first source/drain contacts are disposed between respective first gate structures along the first direction, the second source/drain contacts are disposed between respective second gate structures along the first direction, and the third source/drain contacts are disposed between respective third gate structures along the first direction; and
a first direction extending segment of the third gate structure is not overlapped by the third source/drain contacts in the top view.

17. The device structure of claim 10, wherein the third gate structure includes a gate stack and gate spacers disposed along sidewalls of the gate stack.

18. A device layout comprising:
first active regions in a first device region and second active regions in a second device region, wherein the first active regions extend lengthwise along a first direction and the second active regions extend lengthwise along the first direction;
first line-shaped gates that extend lengthwise over the first active regions along a second direction different from the first direction and second line-shaped gates that extend lengthwise over the second active regions along the second direction; and
an H-shaped gate that extends lengthwise over an isolation region along the second direction, wherein the isolation region extends along the first direction from the first device region to the second device region.

19. The device layout of claim 18, further comprising:
first line-shaped source/drain contact isolations that extend lengthwise along the first direction over the first device region, the isolation region, and the second device region, wherein the first line-shaped source/drain contact isolations extend over second direction extending segments of the H-shaped gate; and
a second line-shaped source/drain contact isolation that extends length wise along the first direction over the first device region, the isolation region, and the second device region, wherein the second line-shaped source/drain contact isolation has a square-shaped profile in the isolation region over a first direction extending segment of the H-shaped gate.

20. The device layout of claim 18, further comprising line-shaped source/drain contacts that extend lengthwise along the second direction without overlapping a first direction extending segment of the H-shaped gate.
